(19) United States
(12) Patent Application Publication
(10) Pub. No.: US 2009/0293947 A1
(43) Pub. Date: Dec. 3, 2009

(54) Photoelectric Conversion Device and Method of Manufacturing the Same, and Photoelectric Power Generation Device

(75) Inventors: Hisashi Higuchi, Shiga (JP); Rui Kamada, Shiga (JP)

Correspondence Address: BIRCH STEWART KOLASCH & BIRCH, PO BOX 747, FALLS CHURCH, VA, 22040-0747, US

(73) Assignee: KYOCERA CORPORATION, Kyoto (JP)

(21) Appl. No.: 12/089,894

(22) PCT Filed: Oct. 10, 2006
(86) PCT No.: PCT/JP2006/320230

§ 371 Date: Jan. 28, 2009

(30) Foreign Application Priority Data
Oct. 11, 2005 (JP) 2005-296371
Feb. 3, 2006 (JP) 2006-027442

(51) Int. Cl. H01L 31/00; H01L 31/18

(52) U.S. Cl. 136/256; 438/69; 257/E21.158

(57) ABSTRACT

This invention provides a photoelectric transducer comprising a light transparent substrate, a light transparent conductive layer provided on the light transparent substrate and a porous semiconductor layer provided on the light transparent conductive layer. The porous semiconductor layer can absorb coloring matter and contains an electrolyte. The photoelectric transducer further comprises a porous spacer layer containing an electrolyte provided on the porous semiconductor layer and a counter electrode layer provided on the porous spacer layer. According to the above constitution, the thickness of the electrolyte layer is determined by the thickness of the spacer layer containing the electrolyte unlike the prior art technique in which the thickness of the electrolyte layer is determined by spacing between two substrates. Accordingly, the electrolyte layer can be formed thinly and evenly and can enhance the photoelectric conversion efficiency and the reliability.

### TECHNICAL FIELD

The present invention relates to a photoelectric conversion device such as a photovoltaic cell and a photo diode with high photoelectric conversion efficiency and reliability, and a method of manufacturing the same.

### BACKGROUND ART

Heretofore, a dye-sensitized solar cell, a type of photoelectric conversion device, has been actively developed. The cell does not require a vacuum apparatus during manufacturing and thus is considered to have a low environment load at low cost, and research and development are therefore performed actively.

This dye-sensitized solar cell conventionally employs a porous titanium oxide layer with a thickness of about 10 μm on a conducting glass substrate. Fine particles of titanium oxide with a mean particle size of about 20 nm are sintered at about 450° C. to form the titanium oxide layer. Then, a photosensitive electrode substrate includes the titanium oxide layer thereon to serve as a photosensitive electrode layer wherein dyes are monomolecularly adsorbed on the surface of titanium oxide grains of the porous titanium oxide layer. An opposing electrode substrate includes a conductive glass substrate and an electrode layer of platinum or carbon on the conducting glass substrate. The photosensitive electrode substrate and the opposing electrode substrate are mutually opposed, and a frame-shaped thermoplastic resin sheet is used as spacer and sealing member, such that both the substrates are sandwiched together by hot pressing. The composition then provides an electrolyte solution including an iodine/iodide redox mediator that is injected and filled between these substrates through holes opened in the opposing electrode substrate, after which the holes of the opposing electrode substrate are closed (refer to Non-patent Document 1).

The surface area of a solar cell is large, and therefore when two large substrates (the photosensitive electrode substrate and the opposing electrode substrate) are attached together, in order to maintain a gap that fills the electrolytes, the insertion of various spacers has been previously investigated.

Regarding a dye-sensitized solar cell including an arrangement of an electrolyte layer between a dye-sensitization photodiode electrode and an opposing electrode in Patent Document 1, it is reported that a solid material (fibrous material) is placed to contain the electrolyte solution in the electrolyte layer between the dye-sensitization photodiode electrode and the opposing electrode.

Patent Document 2 discloses a photoelectric conversion device including an active electrode, an opposing electrode and a solid layer. The active electrode has a semiconductor film which is coated with dye. The opposing electrode is arranged opposite the active electrode. The solid layer includes a porous polymer film which is sandwiched between the active electrode and the opposing electrode. An electrolyte solution is contained in an air gap of the solid layer.

Patent Document 3 discloses a photoelectric conversion device including a conducting supporting member, a semiconductor fine-grain layer with dye adsorbed thereto that is coated on the conducting supporting member, a charge-transfer layer and an opposing electrode layer. The photoelectric conversion device also includes a spacer layer which contains substantially insulating grains between the semiconductor fine-grain layer and the opposing electrode.

Patent Document 1: Japanese Unexamined Patent Publication No. 2000-357544

Patent Document 2: Japanese Unexamined Patent Publication No. 11-339866

Patent Document 3: Japanese Unexamined Patent Publication No. 2000-294306

Non-Patent Document 1: Johokiko Co., Ltd. publication “Leading Edge Technologies and Future Trends in Dye-sensitized and other Solar Cells” P26-P27 (published Apr. 25, 2003)

### DISCLOSURE OF THE INVENTION

### Problems to be Solved by the Invention

However, as in the constitutions of Patent Documents 1, 2 and 3, in the case of a cell structure wherein two substrates of a photosensitive electrode substrate and an opposing electrode substrate are attached together, it is difficult to manufacture a device where a gap between the surface of the porous titanium oxide layer adsorbing (supporting) dye and the opposing electrode surface is filled with electrolyte is kept narrow and constant, and therefore, it is difficult to manufacture a device ensuring high photoelectric conversion efficiency, stability and reliability.

In Patent Document 3, a spacer layer is formed by insulating-type fine particles on an oxide-semiconductor fine-particle layer. The spacer layer and the oxide-semiconductor fine-particle layer are simultaneously formed and simultaneously sintered. However, whereas the mean particle size of the oxide-semiconductor fine particles is small at 10 nm, the mean particle size of alumina powder which is an insulating fine particle is large at 0.8 μm, and the mean particle size of low-melting glass powder is also large at 0.5 μm. A problem arises in the case of alumina powder because a mean grain size of 0.8 μm cannot be achieved by sintering at the sintering temperature of semiconductor fine particles (about 500° C.), and if the sintering temperature is raised any higher, the crystalline structure of the oxide semiconductor changes, which impairs the high conversion efficiency.

Therefore, the present invention was completed in view of the problems described above, and therefore the objects as follows are achieved in the present invention.

First, instead of attaching two substrates together, an object is to reduce the number of substrates by laminating layers on one substrate forming a single body.

Second, the thickness of the electrolyte layer was determined by a gap between two substrates, and another object of the present invention is to allow determination according to the thickness of a spacer layer containing an electrolyte that does not depend on the gap, such that the electrolyte layer can be made both thin and uniform, and the conversion efficiency and reliability can be improved.

Third, a laminated body including a singular laminated structure is formed by laminating layers on one light-transmitting substrate, and then a dye is adsorbed (supported) through a permeation layer and the entirety is immersed in an electrolyte solution, thereby avoiding the deterioration of the dye and the electrolyte that occurs due to process steps such as heat treatment during lamination of the opposing electrode layer after adsorption (support) of the dye and injection of the electrolyte, resulting in the improved conversion efficiency.

It is easy to form a plurality of photoelectric conversion devices on one light-transmitting substrate so that lamination of the devices is excellent. In addition, it is possible to laminate a plurality of photoelectric conversion devices, thereby providing a photoelectric conversion device with excellent lamination properties.

### Means for Solving the Problems

According to the present invention, a photoelectric conversion device includes a light-transmitting substrate; a light-transmitting conductive layer on the light-transmitting substrate; a porous semiconductor layer that adsorbs (supports) a dye and contains the electrolyte, and that is formed on the light-transmitting conductive layer; a porous spacer layer containing the electrolyte and formed on the porous semiconductor layer; and an opposing electrode layer formed on the porous spacer layer.

The photoelectric conversion device preferably includes a sealing layer which covers an upper surface and a side surface of a laminated body and seals the electrolyte in a laminated body that comprises the conductive layer, the porous semiconductor layer, the porous spacer layer and the opposing electrode layer, wherein the laminated body includes the light-transmitting conductive layer, the porous semiconductor layer, the porous spacer layer and the opposing electrode layer respectively laminated in this order on the light-transmitting substrate.

In addition, the porous semiconductor layer preferably includes a sintered body of oxide-semiconductor fine grains and the mean grain size of the oxide-semiconductor fine grains preferably becomes progressively larger in the thickness direction progressing away from a side of the light-transmitting substrate.

Furthermore, the porous spacer layer is preferably a porous body containing fine grains of an insulator or a p-type semiconductor.

Furthermore, the photoelectric conversion device preferably includes an uneven interface between the porous spacer layer and the semiconductor layer.

Furthermore, the opposing electrode layer preferably includes a porous body containing the electrolyte.

The porous spacer layer preferably includes a permeation layer into which an electrolyte solution permeates and inside which the permeated solution is contained.

Furthermore, the arithmetic mean roughness of the surface or a fractured surface of the permeation layer may be larger than the arithmetic mean roughness of the surface or a fractured surface of the porous semiconductor layer.

The arithmetic mean roughness of the surface or a fractured surface of the permeation layer may not be less than 0.1 μm.

The permeation layer may include a sintered body formed by sintering at least one selected from insulator grains and oxide semiconductor grains.

The permeation layer may include a sintered body formed by sintering at least one of aluminum oxide grains and titanium oxide grains.

According to the present invention, the photoelectric conversion device preferably includes a sealing layer that traps the electrolyte therein by covering an upper surface and a side surface of the laminated body.

According to the present invention, the first method of manufacturing a photoelectric conversion device includes steps of laminating a light-transmitting conductive layer, a porous semiconductor layer, a porous spacer layer and an opposing electrode layer in this order on a light-transmitting substrate to form a laminated body, opening one or more through holes that pass completely through the light-transmitting substrate and the light-transmitting conductive layer, injecting a dye through the through hole(s) such that the dye is adsorbed to the porous semiconductor layer, injecting an electrolyte into the interior of the laminated body and closing the through holes.

According to the present invention, the second method of manufacturing a photoelectric conversion device includes steps of laminating a light-transmitting conductive layer, a porous semiconductor layer and a porous spacer layer in this order on a light-transmitting substrate to form a laminated body, immersing the laminated body in a dye solution such that the dye is adsorbed to the porous semiconductor layer, forming an opposing electrode layer on the porous spacer layer, and a step of permeating an electrolyte into the porous spacer layer and the porous semiconductor layer from at least a side surface of the laminated body.

According to the present invention, the third method of manufacturing a photoelectric conversion device includes a steps of laminating a light-transmitting conductive layer, a porous semiconductor layer and a porous spacer layer in this order on a light-transmitting substrate to form a laminated body, immersing the laminated body in a dye solution such that the dye is adsorbed to the porous semiconductor layer of the laminated body, permeating an electrolyte into the porous semiconductor layer and the porous spacer layer of the laminated body from a front surface of the laminated body, and laminating an opposite layer on the porous spacer layer.

According to the present invention, the fourth method of manufacturing a photoelectric conversion device includes steps of laminating a light-transmitting conductive layer, a porous semiconductor layer, a porous spacer layer and an opposing electrode layer in this order on a light-transmitting substrate to form a laminated body, immersing the laminated body in a dye solution such that the dye is adsorbed to the porous semiconductor layer from a side surface of the laminated body and permeating an electrolyte into the porous spacer layer and the porous semiconductor layer of the laminated body from at least a side surface of the laminated body.

According to the present invention, in the above four methods of manufacturing a photoelectric conversion device, the porous spacer layer may serve as the permeation layer.

According to the present invention a photoelectric power generation device is provided such that the photoelectric conversion device of the present invention is utilized as means of electrical power generation, and the electrical power so generated is supplied to a load.

### EFFECTS OF THE INVENTION

According to the present invention, the photoelectric conversion device includes the porous spacer layer on a photosensitive electrode substrate (a light-transmitting substrate and a porous semiconductor layer) and the laminated part (an opposing layer, that is a catalyst layer and an electrode layer) at the opposing electrode side on the porous spacer layer, while the porous spacer layer serves as a supporting layer. Therefore, the substrate at the opposing electrode used in conventional devices can be omitted, and also low cost and simplification of the structure can be achieved.

Since two electrodes (the light-transmitting conductive layer and the conductive layer) are not interposed between two substrates, unlike conventional devices, it is easy to remove the electrodes.

The porous semiconductor layer is formed on a substrate at the opposing electrode side (light-transmitting substrate), and the porous semiconductor layer can be formed at a light-incident side. Therefore, conversion efficiency is high.

The thickness of the electrolyte layer determined previously by a gap between two substrates is allowed to be determined according to the thickness of a porous spacer layer, and thus the electrolyte layer can be made both thin and uniform, and the conversion efficiency and reliability can be improved.

Since the electric resistance is larger than a conventional liquid electrolyte, the conversion efficiency decreases by about 30% with using a solid electrolyte. However, with the laminated body including a light-transmitting conductive layer, a porous semiconductor layer, a porous spacer layer and an opposing electrode layer are laminated in this order on a light-transmitting substrate, like the present invention, the thickness of the electrolyte layer can be remarkably decreased, thus exerting the effect of obtaining high conversion efficiency even if the electrolyte is a solid electrolyte.

The porous semiconductor layer formed by applying a paste including oxide-semiconductor fine grains such as titanium oxide grains, water and a surfactant, and sintering the paste at high temperature shows good conversion efficiency. More specifically, according to the present invention, since a light-transmitting conductive layer can be formed after forming the porous semiconductor layer, adhesion between the porous semiconductor layer and the light-transmitting conductive layer can be improved, and the conversion efficiency and reliability are improved.

Furthermore, since only one substrate, a light-transmitted substrate, is required, it is easy to achieve integration and lamination of a photoelectric conversion device. That is, a plurality of photoelectric conversion devices can be arranged on one substrate and series connection and/or parallel connection can be freely selected and also desired voltage and current can be output. Also, it is easy to laminate a plurality of photoelectric conversion devices. Namely, a laminated photoelectric conversion device including a plurality of photoelectric conversion devices laminated on one substrate can be obtained easily, and such a device exhibits small losses even when the voltage increases.

A sealing layer is preferably formed such that an upper surface and a side surface of a laminated body are covered and the electrolyte is sealed therein. Therefore, it is possible to ensure reliability by suppressing deterioration due to contamination of the dye and the electrolyte from air.

The porous semiconductor layer preferably includes a sintered body of oxide-semiconductor fine grains and the mean grain size of the oxide-semiconductor fine grains becomes progressively larger in the thickness direction progressing away from a side of the light-transmitting substrate. Therefore, it is possible to reflect and scatter easily transmitting long wavelength light on oxide-semiconductor fine grains with a larger mean grain size according to a site of the porous semiconductor layer far from the light-transmitting substrate side, thus making it possible to improve a light confinement effect and to improve the conversion efficiency.

The porous spacer layer is preferably a porous body including fine grains of an insulator or a p-type semiconductor. Therefore, the porous spacer layer plays a role of a supporting layer capable of supporting the upper layer such as a porous semiconductor layer and also has an electric insulating action (prevention of short circuiting), and thus the photoelectric conversion device can be formed of one substrate without laminating two substrates.

Since a conventional porous semiconductor is an n-type semiconductor, a porous spacer layer is used as a p-type semiconductor, and therefore, reverse electron transfer is suppressed by blocking (insulating) transport of electrons from a porous semiconductor to a porous spacer layer, and the porous spacer layer can help a photoelectric converting action because holes have transportability. In a reverse relation, when the porous semiconductor is a p-type semiconductor, the porous spacer layer preferably includes an n-type semiconductor.

The porous spacer layer is capable of containing the pore section of the porous body with an electrolyte and therefore can efficiently perform an oxidation-reduction reaction. Since the thickness of the porous spacer layer containing the electrolyte can be controlled to be both thin and uniform with good reproducibility, the width (thickness) of the electrolyte layer can be controlled both thin and uniform, and as a result electric resistance decreases and also the conversion efficiency and reliability are improved. The width of the electrolyte layer does not depend on the flatness of the light-transmitting substrate, but depends on the thickness of the porous spacer layer, and thus the electrolyte layer can be formed by a known technique of uniform coating. Even if large area size, integration and lamination of the photoelectric conversion device are realized, current loss and voltage loss due to thickness unevenness of the electrolyte layer are not so large and thus a photoelectric conversion device with excellent characteristics can be manufactured even if large area size is realized.

An interface between the porous spacer layer and the porous semiconductor layer preferably includes an uneven face. Therefore, light passed through the porous semiconductor layer is scattered, bringing about a light confinement effect, thus making possible further improvement of the conversion efficiency.

The opposing electrode layer preferably includes a porous body containing the electrolyte. Therefore, the surface area of the opposing electrode layer can be increased and the conversion efficiency can be improved by improving the oxidation-reduction reaction and hole transporting properties.

According to the present invention, the method of manufacturing a photoelectric conversion device includes steps of laminating a light-transmitting conductive layer, a porous semiconductor layer, a porous spacer layer and an opposing electrode are laminated in this order on a light-transmitting substrate to form a laminated body, opening a plurality of through holes that pass completely through the light-transmitting substrate and the light-transmitting conductive, injecting a dye through the through holes such that the dye is adsorbed to the porous semiconductor layer, injecting an electrolyte into the interior of the laminated body, and closing the through holes. Consequently, a photoelectric conversion device with various operations and effects described above can be manufactured.

Since the light-transmitting conductive layer can be formed before dye adsorption, a high-temperature treatment can be used in the formation of the light-transmitting conductive layer, thus exerting the effects of allowing wider selection in the material of the light-transmitting conductive layer and the formation method, and improving conductivity of the light-transmitting conductive layer.

According to the present invention, a permeation layer, serving as a porous spacer layer into which an electrolyte solution permeates and inside which the permeated solution is contained, is formed on a photosensitive electrode substrate (a light-transmitting substrate and a porous semiconductor layer) and a laminated portion (a opposing layer, i.e. a catalyst layer and a conductive layer) at the opposing electrode side is laminated thereon using the permeation layer as a supporting layer. Therefore, the conventionally used substrate at the opposing electrode can be omitted, and also low cost and simplification of the structure can be achieved.

Since the permeation layer is inside the laminated body, adsorbing a dye through a permeation layer and immersing an electrolyte solution into the laminated body through the permeation layer are possible. Therefore, it is possible to prevent deterioration of the dye and the electrolyte that occurs due to steps such as heat treatment during lamination of the opposing electrode layer after adsorbing the dye and injecting the electrolyte in conventional methods, and as a result conversion efficiency is improved.

The arithmetic mean roughness of the surface or a fractured surface of the permeation layer is preferably larger than the arithmetic mean roughness of the surface or a fractured surface of the porous semiconductor layer. Therefore, the mean grain size of fine grains in the permeation layer is larger than that in the porous semiconductor layer. In this case, since the pore size in the permeation layer is large, a large amount of the electrolyte can exist in the permeation layer adjacent to the opposing electrode layer, and thus electric resistance of the electrolyte contained in the permeation layer decreases and the conversion efficiency can be improved.

Since the arithmetic mean roughness of the surface or a fractured surface of the permeation layer is preferably not less than 0.1μ□, it is easy to permeate an electrolytic solution through the permeation layer and also the dye can be sufficiently adsorbed to the porous semiconductor layer.

The permeation layer preferably includes a sintered body which is formed by sintering at least one type of particle selected from an insulator and an oxide semiconductor, and the permeation layer also plays a role of a supporting layer capable of supporting the porous semiconductor layer, and thus a photoelectric conversion device can be formed on one substrate without laminating two substrates.

The permeation layer itself is a porous body. Since the thickness of the permeation layer containing the electrolyte can be controlled to be both thin and uniform, the width (thickness) of the permeation layer serving as the electrolyte layer that contains the electrolyte therein can be controlled to be both thin and uniform like the above-mentioned porous spacer layer, and as a result electric resistance decreases and also the conversion efficiency and reliability are improved. The thickness of the electrolyte layer depends on the thickness of the permeation layer, and thus the electrolyte layer can be formed by using a uniform coating technique conventionally employed. Even if large area size, integration and lamination of the photoelectric conversion device are realized, current loss and voltage loss due to thickness unevenness of the electrolyte layer are not so large, and thus a photoelectric conversion device with high performance can be manufactured even if large area size is realized.

When the permeation layer includes insulator grains, the permeation layer plays a role of a supporting layer capable of supporting a porous semiconductor layer and also has an electric insulation (prevention of short circuit), and thus short circuit between the porous semiconductor layer and the opposing electrode layer can be prevented and also the conversion efficiency can be improved.

The permeation layer preferably includes a sintered body formed by sintering at least one type of particles selected from an aluminum oxide and a titanium oxide. Therefore, adhesion between the permeation layer and the porous semiconductor layer can be improved, and also the conversion efficiency and reliability can be improved.

When the permeation layer includes aluminum oxide grains as insulator grains, short circuit between the porous semiconductor layer and the opposing electrode layer can be prevented, and also the conversion efficiency can be improved.

It is preferable that the permeation layer includes titanium oxide grains which are oxide-semiconductor grains, because an electronic energy band gap is in the range from 2 to 5 eV that is larger than that in the case of visible light, thus exerting the effect that the permeation layer does not absorb light in a wavelength range where the dye absorbs.

According to the present invention, the first to fourth method of manufacturing a photoelectric conversion device can manufacture a photoelectric conversion device with various operations and effects described above.

Since dye can be adsorbed before forming the opposing electrode layer, dye adsorption can be performed more completely, and thus the conversion efficiency is improved.

According to the present invention, in a method of manufacturing a photoelectric conversion device, a light-transmitting conductive layer, a porous semiconductor layer and a porous spacer layer are laminated in this order on a light-transmitting substrate to form a laminated body. Then, the laminated body is immersed in a dye solution such that the dye is adsorbed into the porous semiconductor layer, and then an electrolyte is permeated into the porous semiconductor layer and the porous spacer layer of the laminated body from a front surface of the laminated body. Then, an opposite layer is laminated on the porous spacer layer, and therefore, a photoelectric conversion device with various operations and effects described above can be manufactured. Since dye can be adsorbed before forming the opposing electrode layer, dye adsorption can be performed more completely, and thus the conversion efficiency is improved. Since an electrolyte is permeated before the opposing electrode layer is formed, electrolyte can be permeated more securely, and thus the conversion efficiency is improved. In this case, the electrolyte may be a gel electrolyte or a solid electrolyte, and, for example, the liquefied electrolyte by increasing the temperature thereof is permeated into the porous semiconductor layer and the porous spacer layer and then the solidification of the electrolyte by cooling realizes to laminate the opposing electrode layer on the porous spacer layer easily. Therefore, it is not necessary to permeate the electrolyte later.

According to the present invention, in a method of manufacturing a photoelectric conversion device, a light-transmitting conductive layer, a porous semiconductor layer, a porous spacer layer and an opposing electrode layer are laminated in this order on a light-transmitting substrate to form a laminated body. Then the laminated body is immersed in a dye solution, wherein the dye is adsorbed into the porous semiconductor layer from a side surface of the laminated body, and then the electrolyte solution is permeated into the porous semiconductor layer from at least a side surface of the laminated body. Consequently, a photoelectric conversion device with various operations and effects described above can be manufactured.

According to the method of manufacturing a photoelectric conversion device of the present invention, a light-transmitting conductive layer, a porous semiconductor layer, a permeation layer and an opposing electrode layer are laminated in this order on a light-transmitting substrate to form a laminated body. Then the laminated body is immersed in a dye solution such that the dye is absorbed through the permeation layer and adsorbed to the porous semiconductor layer, and then the electrolyte solution is permeated through the permeation layer into the porous semiconductor layer. Consequently, a photoelectric conversion device with various operations and effects described above can be manufactured.

According to the present invention, the photoelectric power generation device utilized the photoelectric conversion device described above as means of electrical power generation, and the electrical power generated by the means of electrical power generation is supplied to a load. Therefore, a highly reliable photoelectric power generation device having high conversion efficiency can be obtainable by utilizing the effect, which is the effect of the photoelectric conversion device described above, capable of stably obtaining excellent photoelectric conversion characteristics in which the width of the electrolyte is thin and uniform.

### BRIEF DESCRIPTION OF THE DRAWINGS

FIG. 1 is a schematic sectional view showing a photoelectric conversion device according to an embodiment of the present invention.

FIG. 2 is a schematic sectional view showing a modified example of FIG. 1.

FIG. 3 is a schematic sectional view showing another modified example of FIG. 1.

FIG. 4 is a schematic sectional view showing a photoelectric conversion device according to another embodiment of the present invention.

FIG. 5 is a schematic sectional view showing a modified example of FIG. 4.

FIG. 6 is a schematic sectional view showing another modified example of FIG. 4.

FIG. 7 illustrates the first method of manufacturing a photoelectric conversion device according to the present invention.

FIG. 8 illustrates the second method of manufacturing a photoelectric conversion device according to the present invention.

FIG. 9 illustrates the third method of manufacturing a photoelectric conversion device according to the present invention.

FIG. 10 illustrates the fourth method of manufacturing a photoelectric conversion device according to the present invention.

### PREFERRED EMBODIMENTS FOR CARRYING OUT THE INVENTION

### First Embodiment

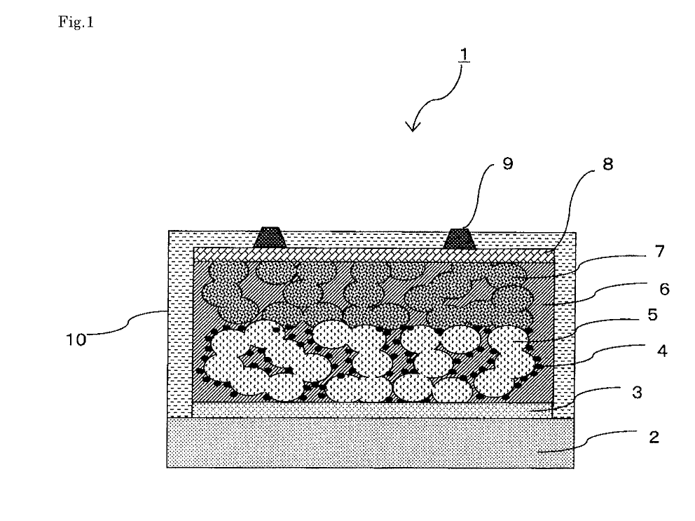

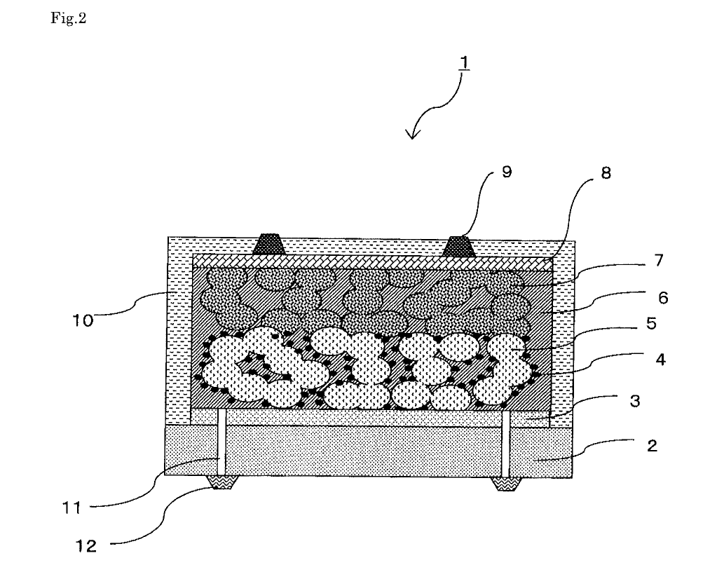

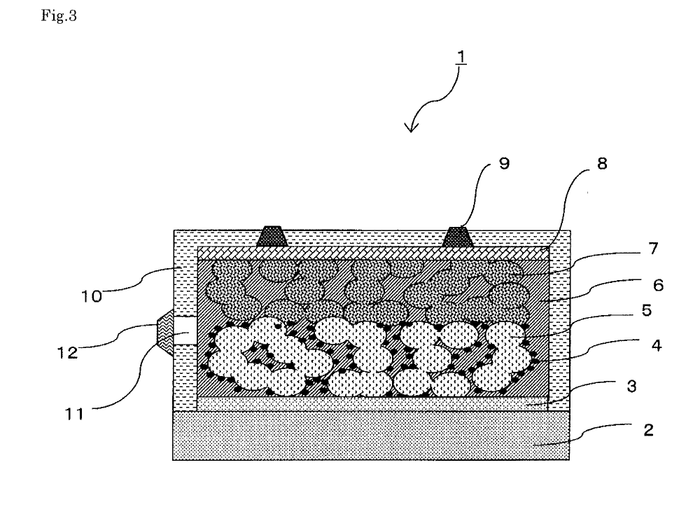

Herewith, an embodiment of the present invention relating to a photoelectric conversion device, a method of manufacturing the same and an photoelectric power generation device are described in detail below with reference to FIG. 1 through FIG. 3. Since photoelectric conversion devices shown in FIGS. 2 and 3 are same as that shown in FIG. 1 except a through hole 11 and a sealing member 12 sealing the through hole, the same reference numerals are used for the same members in the drawings and the explanation of the details thereof are omitted.

FIG. 1 illustrates a photoelectric conversion device according to an embodiment of the present invention. The photoelectric conversion device 1 of FIG. 1 includes a laminated body which is formed by a light-transmitting conductive layer 3, a porous semiconductor layer 5 that adsorbs (loads) a dye 4 as well as contains the electrolyte 6 and an opposing electrode layer 8 that are laminated in this order on a light-transmitting substrate 2 to form a laminated body. A sealing layer 10 is formed on and at side of the laminated body.

Herewith, the elements included in the photoelectric conversion device 1 recited above are described in detail below.

### <Light-Transmitting Substrate>

Any substrates having light-transmitting property can be used as the light-transmitting substrate 2. For example, light-transmitting substrate 2 may be an inorganic material including glass such as white plate glass, soda glass or borosilicate glass or ceramics; a resin material such as polyethylene terephthalate (PET), polycarbonate (PC), acryl, polyethylene naphthalate (PEN) or polyimide; or an organic inorganic hybrid material.

The thickness of the light-transmitting substrate 2 may be in the range from 0.005 to 5 mm, and preferably from 0.01 to 2 mm in view of the mechanical strength.

### <Light-Transmitting Conductive Layer>

For the light-transmitting conductive layer 3, a metal oxide doped with fluorine or metal can be used. Of these layers, a fluorine-doped tin dioxide film (SnO₂:F film) formed by a thermal CVD method is preferred. A tin-doped indium oxide film (ITO film) and an impurity-doped indium oxide film (In₂O₃ film) formed at low temperature by a sputtering method and a spray pyrolysis deposition method are preferred. In addition, an impurity-doped zinc oxide film (ZnO film) formed by a solution growth method is preferred. Also, these light-transmitting conductive layers 3 may be laminated in various combinations.

The thickness of the light-transmitting conductive layer 3 may be in the range from 0.001 to 10 μm, and preferably from 0.05 to 2.0 μm. When the thickness is less than 0.001 μm, resistance of the light-transmitting conductive layer increases. In contrast, when the thickness exceeds 10 μm, light transmittance of the conductive layer deteriorates.

Examples of other film formation methods of the light-transmitting conductive layer 3 include a vacuum deposition method, an ion plating method, a dip coating method and a sol-gel method. By the growth of these films, the surface of the light-transmitting conductive layer 3 preferably includes an uneven interface in the order of a wavelength of incident light thereby bringing about a light confinement effect.

The light-transmitting conductive layer 3 may be an extremely thin metal film such as Au, Pd or Al formed by a vacuum deposition method or a sputtering method.

### <Porous Semiconductor Layer>

The porous semiconductor layer (oxide semiconductor layer) 5 is preferably a porous n-type oxide-semiconductor layer such as titanium dioxide. As shown in FIG. 1, the porous semiconductor layer 5 is formed on the light-transmitting conductive layer 3.

Titanium oxide (TiO₂) is an optimal material or composition for the porous semiconductor layer 5. Other useful materials are a metal oxide-semiconductor made of at least one kind of metal element such as titanium (Ti), zinc (Zn), tin (Sn), niobium (Nb), indium (In), yttrium (Y), lanthanum (La), zirconium (Zr), tantalum (Ta), hafnium (Hf), strontium (Sr), barium (Ba), calcium (Ca), vanadium (V) and tungsten (W). The material may also contain one or more kinds of non-metal elements such as nitrogen (N), carbon (C), fluorine (F), sulfur (S), chlorine (Cl) and phosphorus (P). It is preferable that titanium oxide has an electronic energy band gap in the range from 2 to 5 eV that is larger than the energy of visible light. The porous semiconductor layer 5 may be an n-type semiconductor having a conduction band lower than that of the dye 4 in an electronic energy level.

Because the porous semiconductor layer 5 is a porous body including a granular body, a fibrous body such as an acicular body, tubular body or columnar body, or a collection of these various fibrous bodies, such that the surface area that adsorbs the dye 4 increases thus allowing improved conversion efficiency. It is preferable for the porous semiconductor layer 5 to be a porous body having a void fraction of 20% to 80%, and more preferably 40% to 60%. A porous body allows the surface area as a photosensitive electrode layer to be improved by a factor of 1,000 or more as compared to that of a non-porous body, and thus high efficiency of light absorption, photoelectric conversion and electronic conduction can be obtained.

The porosity of the porous semiconductor layer 5 can be obtained by the following procedure. Using a gas adsorption measuring apparatus, an isothermal adsorption curve of a sample is determined by a nitrogen gas adsorption method and the volume of pores is determined by a BJH (Barrett-Joyner-Halenda) method, a CI (Chemical Ionization) method or a DH (Dollimore-Heal) method, and then the porosity can be obtained from the resulting volume of pores and density of grains of the sample.

It is preferable that the shape of grains in the porous semiconductor layer 5 is such that the surface area of the same is large and the electrical resistance is low, for example that obtained by a composition of fine grains or a fine fibrous body. The mean grain size or the mean fiber diameter of the same is in the range from 5 to 500 nm, and more preferably from 10 to 200 nm. This is because miniaturization of the mean grain size or the mean fiber diameter of material is not possible for the lower limit of 5 nm or less, and the contacting surface area becomes small and thus photocurrent becomes markedly low when the upper limit of 500 nm is exceeded.

Furthermore, being a porous body as the porous semiconductor layer 5 which absorbs dye 4, the dye-sensitized photoelectric converting body has an uneven surface which brings about a light confinement effect, and thus the conversion efficiency can be further improved.

The thickness of the porous semiconductor layer 5 is preferably in the range from 0.1 to 50 μm, and more preferably from 1 to 20 μm. This is because the photoelectric conversion markedly decreases and is not suitable for a practical use when the thickness is less than the lower limit of 0.1 μm. Light does not permeate the layer and light is not made incident when the thickness exceeds the upper limit of 50 μm.

When the porous semiconductor layer 5 includes titanium oxide, it is formed by the following procedure. First, acetylacetone is added to a TiO₂ anatase powder and the mixture is kneaded with deionized water to prepare a paste of titanium oxide stabilized with a surfactant. The paste thus prepared is applied on a porous spacer layer 7 at a constant speed using a doctor blade method or a bar coating method and then subjected to a heat treatment in atmospheric air at 300 to 600° C., preferably at 400 to 500° C., for 10 to 60 minutes, preferably for 20 to 40 minutes to form a porous semiconductor layer 5. This technique is simple and is preferable.

The low-temperature growth method of the porous semiconductor layer 5 is preferably an electrodeposition method, a cataphoretic electrodeposition method or a hydrothermal synthesis method. The porous semiconductor layer is preferably subjected to a microwave treatment, a plasma treatment using a CVD method, a thermal catalyst treatment or a UV irradiation treatment as a post-treatment for improving electron transportation characteristics. The porous semiconductor layer 5 formed by the low-temperature growth method is preferably porous ZnO formed by the electrodeposition method or porous TiO₂ formed by the cataphoretic electrodeposition method.

The porous surface of the porous semiconductor layer 5 is preferably subjected to a TiCl₄ treatment, namely, a treatment of immersing in a TiCl₄ solution for 10 hours, washing with water and sintering at 450° C. for 30 minutes, because electron conductivity is improved, thus improving the conversion efficiency.

Also, an extremely thin dense layer of an n-type oxide-semiconductor may be inserted between the porous semiconductor layer 5 and the light-transmitting conductive layer 3, because reverse current can be suppressed, thus improving the conversion efficiency.

It is preferable that the porous semiconductor layer 5 includes a sintered body of oxide-semiconductor fine particles and the mean grain size of oxide-semiconductor fine grains becomes progressively bigger progressing away in the thickness direction from a side of the light-transmitting substrate 2. For example, the porous semiconductor layer 5 preferably includes a laminated body of two layers each having a different mean grain size of oxide-semiconductor fine grains. Specifically, oxide-semiconductor fine grains having a small mean grain size are used at a side of the light-transmitting substrate 2 and oxide-semiconductor fine grains having a large mean grain size are used at a side of the porous spacer layer 7, bringing about a light confinement effect of light scattering and light reflection in the porous semiconductor layer 5 at a side of the porous spacer layer 7 having a large mean grain size, thus making possible improvement of the conversion efficiency.

More specifically, it is preferable that 100% (% by weight) of oxide-semiconductor fine grains having a mean grain size of about 20 nm are used as those having a small mean grain size and 70% by weight of oxide-semiconductor fine grains having a mean grain size of about 20 nm and 30% by weight of oxide-semiconductor fine grains having a mean grain size of about 180 nm are used in combination as those having a large mean grain size. An optimum light confinement effect is obtained by varying the weight ratio, the mean grain size and the film thickness. By increasing the number of layers from 2 to 3 or forming these layers so as not to produce a boundary between them, the mean grain size can become progressively bigger progressing away from a side of the light-transmitting substrate 2.

### <Porous Spacer Layer>

The porous spacer layer 7 may be a thin film including a porous body obtained by sintering alumina fine grains. As shown in FIG. 1, the porous spacer layer 7 is formed on the porous semiconductor layer 5.

An aluminum oxide (Al₂O₃) may be most suited for use as the material or composition of the porous spacer layer 7, and the other material may be an insulating (electronic energy band gap is 3.5 eV or more) metal oxide such as silicon oxide (SiO₂).

When the porous spacer layer is a porous body including a collection of these granular bodies, acicular bodies, columnar bodies and/or the like, the porous spacer layer can contain the electrolyte 6 thus allowing improved conversion efficiency.

The porous spacer layer 7 may be a porous body having porosity in the range from 20 to 80%, and more preferably from 40 to 60%. The mean grain size or the mean fiber diameter of the granular body, the acicular body and the columnar body, each constituting the porous spacer layer 7, may be in the range from 5 to 800 nm, and more preferably from 10 to 400 nm. This is because miniaturization of the mean grain size or the mean fiber diameter of the material is not possible when the mean grain size is lower than the lower limit of 5 nm, and the sintering temperature increases when the mean grain size exceeds the upper limit of 800 nm.

When the porous spacer layer 7 has high porosity, resistance of the electrolyte is small and the conversion efficiency can be further improved. For example, a mixture prepared by mixing 70% by weight of fine particles (mean particle size: 30 nm) of aluminum oxide (Al₂O₃) with 30% by weight of fine particles (mean particle size: 180 nm) of titanium oxide having a larger mean particle size than that of Aluminum oxide may be used. Larger porosity can also be obtained by adjusting the weight ratio, the mean particle size and the material.

When the porous spacer layer 7 is a porous body, the surface of the porous spacer layer 7 or the porous semiconductor layer 5 and the interface include an uneven face, bringing about a light confinement effect, thus making possible further improvement of the conversion efficiency.

The porous spacer layer 7 made of alumina is manufactured by the following procedure. First, acetylacetone is added to an Al₂O₃ fine powder and the mixture is kneaded with deionized water to prepare a paste of aluminum oxide stabilized with a surfactant. The paste thus prepared is applied on an opposing electrode layer 8 at a constant speed using a doctor blade method or a bar coating method, and then subjected to a heat treatment in atmospheric air at 300 to 600° C., preferably at 400 to 500° C., for 10 to 60 minutes, preferably for 20 to 40 minutes, to form the porous spacer layer 7.

When the porous spacer layer 7 includes an inorganic p-type metal oxide-semiconductor, the material is preferably CoO, NiO, FeO, Bi₂O₃, MoO₂, Cr₂O₃, SrCu₂O₂ or CaO—Al₂O₃, and MoS₂ may be used.

When the porous spacer layer 7 includes an inorganic p-type compound semiconductor, the material may be CuI, CuInSe₂, Cu₂O, CuSCN, Cu₂S, CuInS₂, CuAlO, CuAlO₂, CuAlSe₂, CuGaO₂, CuGaS₂ or CuGaSe₂, each containing a monovalent copper, and may also be GaP, GaAs, Si, Ge, or SiC.

The low-temperature growth method of the porous spacer layer 7 may be an electrodeposition method, a cataphoretic electrodeposition method or a hydrothermal synthesis method.

The thickness of the porous spacer layer 7 may be in the range from 0.01 to 300 μm, and preferably from 0.05 to 50 μm.

When the porous spacer layer 7 serves as a charge transporting layer containing a p-type semiconductor such as nickel oxide, the manufacturing method is as follows. First, ethyl alcohol is added to a powder of a p-type semiconductor and the mixture is kneaded with deionized water to prepare a paste of a p-type semiconductor stabilized with a surfactant. The paste thus prepared is applied on a porous semiconductor layer 5 at a constant speed using a doctor blade method or a bar coating method and then subjected to a heat treatment in atmospheric air at 300 to 600° C., preferably at 400 to 500° C., for 10 to 60 minutes, preferably for 20 to 40 minutes, to form a charge transporting layer of a p-type semiconductor of a porous body. This technique is simple and is effective when the porous spacer layer can be preliminarily formed on a heat-resistant substrate. In order to form a charge transporting layer containing a p-type semiconductor by forming a pattern in plan view, it is preferred to use a screen printing method as compared with a doctor blade method and a bar coating method.

The low-temperature growth method of the charge transporting layer containing a porous p-type semiconductor is preferably an electrodeposition method, a cataphoretic electrodeposition method or a hydrothermal synthesis method. The charge transporting layer is preferably subjected to a microwave treatment, a plasma treatment or a UV irradiation treatment as a post-treatment for improving hole transportation characteristics. When the p-type semiconductor includes nickel oxide, it is preferably made of nickel oxide having a molecular structure in which nanosize grains are arranged in the form of a fiber by adjusting the kind and the amount of additives to be added to the material solution and devising sintering conditions.

The sintering temperature of fine particles for the porous spacer layer 7 is preferably higher than the sintering temperature of the porous semiconductor layer 5 and also the mean grain size of fine grains of the porous spacer layer 7 is preferably larger than the mean grain size of the porous semiconductor layer 5. In this case, electric resistance of the electrolyte 6 is low, thus making it possible to improve the conversion efficiency.

The porous spacer layer 7 provides electrical insulation between the semiconductor layer 5 and the opposing electrode layer 3, and also serves as a spacer between the semiconductor layer 5 and the opposing electrode layer 3. It is preferred that the porous spacer layer 7 has a uniform thickness, is as thin as possible, and is porous so as to contain the electrolyte 6. As the thickness of the porous spacer layer 7 decreases, namely, the oxidation-reduction reaction distance or the hole transportation distance decreases, the conversion efficiency improves. Also, when the thickness of the porous spacer layer becomes more uniform, a large-area photoelectric conversion device with high reliability can be realized.

### <Opposing Electrode Layer>

As the opposing electrode layer 8, a catalyst layer and a conductive layer (not shown) are preferably laminated in this order from a side of the porous spacer layer 7.

The catalyst layer is preferably an ultrathin film having a catalyst function made of platinum or carbon. In addition, a film obtained by electrodeposition of an ultrathin film made of gold (Au), palladium (Pd) or aluminum (Al) is exemplified. When a porous film made of fine grains of these materials, for example, a porous film of carbon fine grains is used, the surface area of the opposing electrode layer 8 is large, thus making it possible to fill the pore section with the electrolyte 6 and to improve the conversion efficiency. The catalyst layer may be thin and can be made light-transmitting.

The conductive layer compensates conductivity of the catalyst layer. The conductive layer can be used in both non-light-transmitting and light-transmitting applications. The material of the non-light-transmitting conductive layer is preferably titanium, stainless steel, aluminum, silver, copper, gold, nickel or molybdenum. Also, the material may be a resin or conductive resin that contains fine grains or microfine fibers of carbon or metal. The material of a light reflective non-light-transmitting conductive layer is preferably a glossy thin metal film made of aluminum, silver, copper, nickel, titanium or stainless steel used alone, or a material in which a film including an impurity-doped metal oxide made of the same material as that of the light-transmitting conductive layer 3 is formed on a glossy metal thin film so as to prevent corrosion due to the electrolyte 6. Other conductive layers preferably include a multi-layered laminated body with improved adhesion, corrosion resistance and light reflectivity obtained by laminating a Ti layer, an Al layer and a Ti layer in this order. These conductive layers can be formed by a vacuum deposition method, an ion plating method, a sputtering method or an electrolytic deposition method.

The light-transmitting conductive layer preferably includes a tin-doped indium oxide film (ITO film), an impurity-doped indium oxide film (In₂O₃ film), a impurity-doped tin oxide film (SnO₂ film) or an impurity-doped zinc oxide film (ZnO film) formed at low-temperature by a sputtering method or a low-temperature spray pyrolysis deposition method. A fluorine-doped tin dioxide film (SnO₂:F film) formed by a thermal CVD method is preferred in view of low cost. Also, a laminated body with improved adhesion obtained by laminating a Ti layer, an ITO layer and a Ti layer in this order is preferred. In addition, an impurity-doped zinc oxide film (ZnO film) formed by a simple solution growth method is preferred.

Examples of the other film formation method of these films include a vacuum deposition method, an ion plating method, a dip coating method and a sol-gel method. It is preferred to form an uneven face on the order of a wavelength of incident light by these film formation methods because a light confinement effect is obtained. The light-transmitting conductive layer may be an thin metal film with light-transmitting property, such as Au, Pd or Al formed by a vacuum deposition method or a sputtering method. The thickness of the light-transmitting conductive layer is preferably in the range from 0.001 to 10 μm, and more preferably from 0.05 to 2.0 μm, in view of high conductivity and high light transmittance.

Here, when the opposing electrode layer 8 has light-transmitting property, light can be made incident from either of both faces of a principal surface of the photoelectric conversion device 1, and thus the conversion efficiency can be improved by making light to be incident from both faces of the principal surface. The thickness of the conductive layer is preferably in the range from 0.001 to 10 μm, and more preferably from 0.05 to 2.0 μm.

### <Collecting Electrode>

A collecting electrode 9 is not necessary if the opposing layer includes a catalyst layer and a light-transmitting conductive layer. However, if light incidents from the light-transmitting substrate 2 or from the opposing electrode layer 8, a collecting electrode 9 may be needed. Without the collecting electrode 9, the catalyst layer and conductive layer should be thinner so as to make the opposing electrode layer 8 light-transmitting or the conductive layer should be a light-transmitting conductive layer, resulting in the increase in electric resistance of the opposing electrode layer 8 only with the catalyst layer.

### <Collecting Electrode>

The material of the collecting electrode 9 is obtained by applying a conductive paste including conductive particles such as silver, aluminum, nickel, copper, tin or carbon, an epoxy resin as an organic matrix, and a curing agent and firing the conductive paste. The conductive paste is particularly preferably an Ag paste or an Al paste, and both a low-temperature paste and a high-temperature paste can be used. A collecting electrode 9 made of a metal-deposited film can be used by patterning of the film.

### <Sealing Layer>

In FIG. 1, a sealing layer 10 is provided so as to prevent leakage of an electrolyte 6 to the exterior, increase mechanical strength, protect a laminated body and prevent deterioration of a photoelectric conversion function as a result of direct contact with the external environment.

The material of the sealing layer 10 is particularly preferably a fluororesin, a silicone polyester resin, a high-weatherability polyester resin, a polycarbonate resin, an acrylic resin, a PET (polyethylene terephthalate) resin, a polyvinyl chloride resin, an ethylene-vinyl acetate (EVA) copolymer resin, polyvinyl butyral (PVB), an ethylene-ethyl acrylate (EEA) copolymer, an epoxy resin, a saturated polyester resin, an amino resin, a phenol resin, a polyamideimide resin, a UV curing resin, a silicone resin, a urethane resin or a coating resin used for a metal roof because it is excellent in weatherability.

The thickness of the sealing layer 10 may be in the range from 0.1 μm to 6 mm, and preferably from 1 μm to 4 mm. Also, by imparting antidazzle properties, heat shielding properties, heat resistance, low staining properties, antimicrobial, mildew resistance, design properties, high workability, scratching/abrasion resistance, snow slipperiness, antistatic properties, far-infrared radiation properties, acid resistance, corrosion resistance and environment adaptability to the sealing layer 10, reliability and merchantability can be improved more.

It is preferable that the sealing layer 10 has light-transmitting property. It makes light incident from either of both faces of a principal surface of the light-transmitting substrate 2, and thus the conversion efficiency can be improved.

### <Dye>

The dye 4 as a sensitizing dye is preferably a ruthenium-tris, ruthenium-bis, osmium-tris or osmium-bis type transition metal complex, a multinuclear complex, a ruthenium-cis-diaqua-bipyridyl complex, phthalocyanine, porphyrin, a polycyclic aromatic compound, or a xanthene-based dye such as rhodamine B.

In order that the porous semiconductor layer 5 adsorbs the dye 4 thereon, it is effective that the dye 4 contains at least one carboxyl group, sulfonyl group, hydroxamic acid group, alkoxy group, aryl group and phosphoryl group as a substituent. Herein, the substituent preferably enables strong chemical adsorption of the dye 4 to the porous semiconductor layer 5 and easy transfer of charges from the dye 4 in an excitation state to the porous semiconductor layer 5.

The method of adsorbing the dye 4 to the porous semiconductor layer 5 includes, for example, a method of immersing the porous semiconductor layer 5 which is formed on the light-transmitting substrate 2 in a solution containing the dye 4 dissolved therein.

In the manufacturing method of the present invention, a dye 4 is adsorbed to a porous semiconductor layer 5 during the process.

As the solvent of the solution into which the dye 4 is dissolved, for example, alcohols such as ethanol; ketones such as acetone; ethers such as diethylether; and nitrogen compounds such as acetonitrile are used alone or a mixture of two or more kinds of them. The concentration of the dye 4 in the solution is preferably in the range from about 5×10⁻⁵ to 2×10⁻³ mol/l (liter: 1,000 cm³).

There are no restrictions on the solution and temperature conditions of the atmosphere in the case of immersing the light-transmitting substrate 2 with the porous semiconductor layer 5 formed thereon in the solution containing the dye 4 dissolved therein. For example, the light-transmitting substrate 2 is immersed in the solution under atmospheric pressure or a vacuum at room temperature or while heating. The immersion time can be appropriately controlled according to the kind of dye 4 and solution, and the concentration of the solution. Consequently, the dye 4 can be adsorbed to the porous semiconductor layer 5.

### <Electrolyte>

The electrolyte 6 may be an electrolyte solution, an ion-conductive electrolyte such as a gel electrolyte and a solid electrolyte, or an organic hole-transporting material.

As the electrolyte solution, a solution of a quaternary ammonium salt or a Li salt is used. The electrolyte solution can be prepared by mixing ethylene carbonate, acetonitrile or methoxypropionitrile with tetrapropylammonium iodide, lithium iodide or iodine.

The gel electrolyte is roughly classified into a chemical gel and a physical gel. Regarding the chemical gel, a gel is formed by a chemical bond through a crosslinking reaction or the like, while a gel is formed at approximately room temperature through a physical interaction regarding the physical gel. The gel electrolyte is preferably a gel electrolyte obtained by mixing acetonitrile, ethylene carbonate, propylene carbonate or a mixture thereof with a host polymer such as polyethylene oxide, polyacrylonitrile, polyvinylidene fluoride, polyvinyl alcohol, polyacrylic acid or polyacrylamide and polymerizing the mixture. When the gel electrolyte or the solid electrolyte is used, it is possible to gelatinize or solidify by mixing a precursor with low viscosity and a porous semiconductor layer 7 and causing a two-dimensional or three-dimensional crosslinking reaction through means such as heating, ultraviolet irradiation or electron beam irradiation.

The ion-conductive solid electrolyte is preferably a solid electrolyte including a salt such as a sulfone imidazolium salt, a tetracyanoquinodimethane salt or a dicyanoquinodiimine salt in polyethylene oxide or a polymer chain of polyethylene oxide or polyethylene. As the molten salt of iodide, for example, an iodide such as an imidazolium salt, a quaternary ammonium salt, an isooxazolidinium salt, an isothiazolidinum salt, a pyrazolidium salt, a pyrrolidinium salt or a pyridinium salt can be used.

The molten salt of the iodide may include 1,1-dimethylimidazolium iodide, 1-methyl-3-ethylimidazolium iodide, 1-methyl-3-pentylimidazolium iodide, 1-methyl-3-isopentylimidazolium iodide, 1-methyl-3-hexylimidazolium iodide, 1-methyl-3-ethylimidazolium iodide, 1,2-dimethyl-3-propylimidazole iodide, 1-ethyl-3-isopropylimidazolium iodide and pyrrolidinium iodide.

### (Method of Manufacturing Photoelectric Conversion Device)<

### First Embodiment of Manufacturing Method

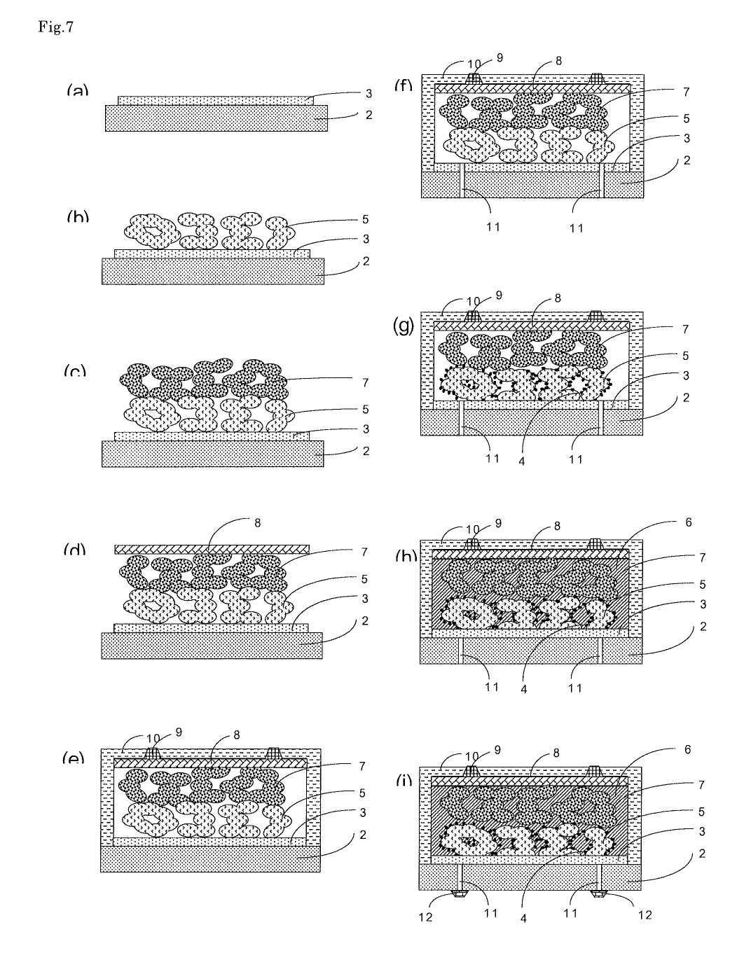

The first manufacturing method is for manufacturing a photoelectric conversion device shown in FIG. 2. That is, a light-transmitting conductive layer 3, a porous semiconductor layer 5, a porous spacer layer 7 and an opposing layer 8 are formed in this order on a light-transmitting substrate 2 to form a laminated body on a substrate. Then, a plurality of through holes 11 (shown in FIG. 2) that pass completely through the light-transmitting substrate 2 and the light-transmitting electrode layer 3 are formed. Then, a dye 4 is injected through the through holes 11 such that the dye 4 is adsorbed to the porous semiconductor layer 5 and then an electrolyte is injected into the interior of the laminated body and then the through holes 11 are sealed. The details are explained below using FIG. 7. A light-transmitting conductive layer 3 made of fluorine-doped tin dioxide, for example, is deposited on a light-transmitting substrate 2 (e.g. glass substrate) by a vacuum deposition method or an ion plating method (FIG. 7(a)).

A porous semiconductor layer 5 such as titanium dioxide is formed on the light-transmitting substrate 2 (FIG. 7(b)). The porous semiconductor layer 7B is formed by the following procedure. First, acetylacetone is added to a TiO₂ anatase powder and the mixture is kneaded with deionized water to prepare a titanium oxide paste stabilized with a surfactant. The paste thus prepared is applied on the light-transmitting conductive layer 3 on the light-transmitting substrate 2 at a constant speed using a doctor blade method and then fired in atmospheric air at the temperature in the range from 300° C. to 600° C. for the time period in the range of 10 to 60 minutes.

Then, a porous spacer layer 7 made of aluminum is formed on the light-transmitting substrate 2 (FIG. 7(c)). The porous spacer layer 7 is formed by the following procedure. First, acetylacetone is added to an Al₂O₃ powder and the mixture is kneaded with deionized water to prepare an alumina paste stabilized with a surfactant. The paste thus prepared is applied on the light-transmitting substrate 2 at a constant speed using a doctor blade method and then fired in atmospheric air at the temperature in the range from 300° C. to 600° C. for the time period in the range of 10 to 60 minutes.

A platinum layer is deposited as an opposing electrode layer in a thickness of 20 to 80 nm on the porous spacer layer 7, using a vacuum deposition method, a sputtering method and the like with Pt target. A Ti layer is deposited on the Platinum layer using a Ti target so as to control sheet resistance in the range from 1 to 5Ω/□ (square) to form a laminated body (FIG. 7(d)).

Then, Ag paste is applied on a portion of the Ti layer and the paste is heated to form an extract electrode 9 (not shown). On the other hand, the light-transmitting conductive layer 3 made of a metal oxide doped with fluorine is soldered using ultrasonic waves (FIG. 7(e)) to form another extract electrode (not shown).

Then, a sheet of a sealing material such as an olefinic resin covers the opposing electrode layer 8, and then is heated to form a sealing layer 10 (FIG. 7(e)).

While, for example, the light-transmitting substrate 2 is ground from the back surface by rotating an electrodeposition diamond bar around an axis at high speed, a plurality of through holes 11 is formed in the light-transmitting substrate 2 (FIG. 7(f)).

Then, the inside of the laminated body formed on the light-transmitting substrate 2 is evacuated through the through holes 11 and then a dye 4 solution is injected into the laminated body through the through holes 11 (FIG. 7(g)).

Then, the inside of the laminated body is evacuated again through the through holes 11 and then an electrolytic 6 solution is injected into the laminated body through the through holes 11 (FIG. 7(h)). Finally, the through holes 11 are closed by a sealing member 12 which includes the same material as the sealing layer 10 (FIG. 7(i)). The photoelectric conversion device according to the present invention is manufactured by the foregoing processes.

### Second Embodiment of Manufacturing Method

The second manufacturing method is for manufacturing a photoelectric conversion device shown in FIG. 3. That is, a light-transmitting conductive layer 3, a porous semiconductor layer 5 and a porous spacer layer 7 are formed in this order on a light-transmitting substrate 2 to form a laminated body on a substrate. Then, the laminated body is immersed in a dye 4 solution thereby adsorbing a dye 4 to the porous semiconductor layer 5 of the laminated body and then an opposing electrode layer 8 is laminated on the porous spacer layer 7. Then, an electrolyte 6 is permeated into the porous spacer layer 7 and the porous semiconductor layer 5 from at least a side surface of the laminated body through holes 11.

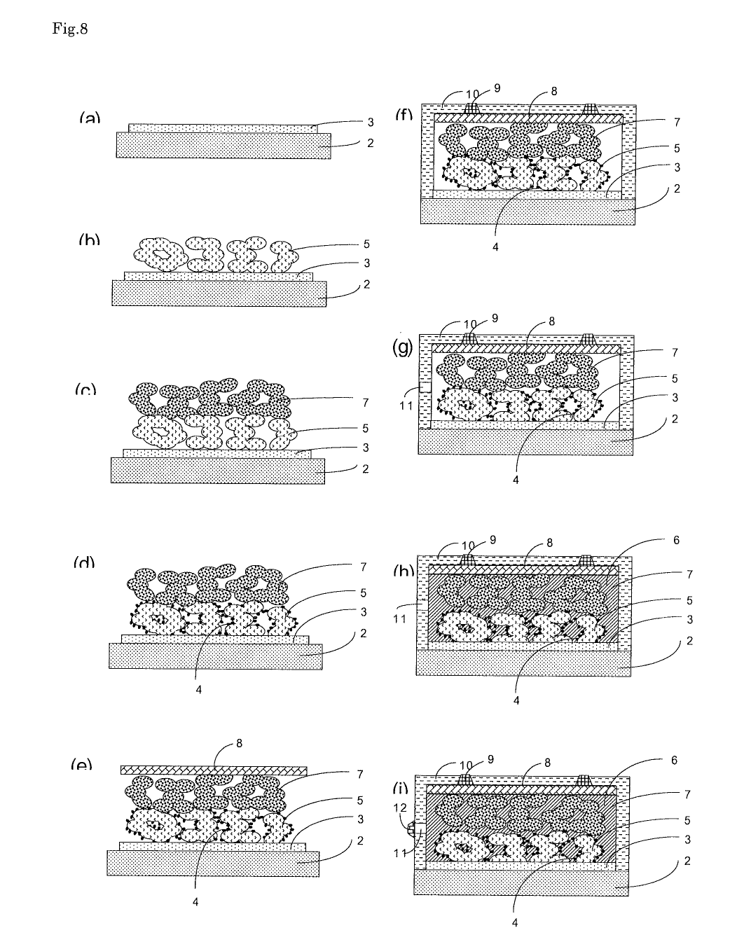

The details are explained below using FIG. 8. A light-transmitting conductive layer 3 made of fluorine-doped tin dioxide is deposited by a vacuum deposition method or an ion plating method (see FIG. 8(a)) on a glass substrate which serves as the light-transmitting substrate 2.

A porous semiconductor layer 5 such as titanium dioxide is formed on the light-transmitting substrate 2 in the same manner of Example 1 (see FIG. 8(b)). Then, a porous spacer layer 7 such as alumina (see FIG. 8(c)) is formed on the porous semiconductor layer 5 in the same manner of Example 1. Then, the laminated body which includes the light-transmitting conductive layer 3, the porous semiconductor layer 5 and the porous spacer layer 7 in this order on a light-transmitting substrate is immersed in a dye 4 solution for 10 to 14 hours thereby adsorbing a dye 4 to the porous semiconductor layer 5.

Then, an opposing electrode layer 8, an extract electrode 9 and the other electrode are formed on the porous spacer layer 7 in the same manner of Example 1, and then a sealing layer is formed (see FIG. 8(e),(f)).

On a side of the sealing layer 10, through holes are formed by cutting a side portion of the sealing layer 10 (FIG. 8(g)) and an electrolyte 6 is injected from a side surface of the laminated body into the laminated body through the through holes 11 (see FIG. 8(h)). Iodine (I₂) and lithium iodide (LiI) in an acetonitrile solution are used as the liquid electrolyte 6. The electrolyte solution is permeated into the inside of the laminated body from a side surface from the laminated body followed by sealing the through holes 11 are with the same sealing member 12 of the same material as that in the sealing layer 10 (see FIG. 8(i)).

### Third Embodiment of Manufacturing Method

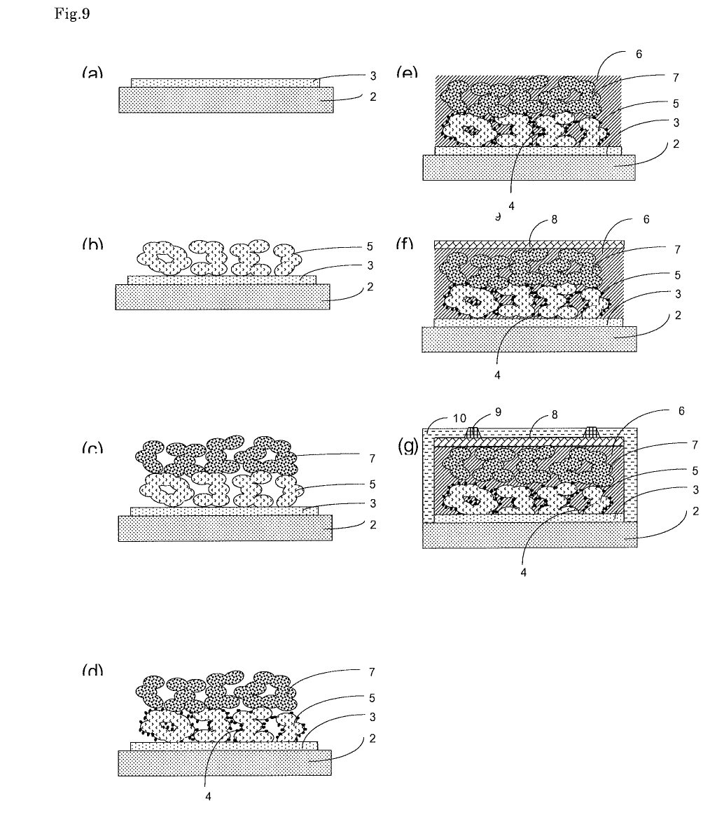

The third manufacturing method is for manufacturing a photoelectric conversion device shown in FIG. 1. That is, a light-transmitting conductive layer 3, a porous semiconductor layer 5 and a porous spacer layer 7 are formed in this order on a light-transmitting substrate 2 to form a laminated body on a substrate. Then, the laminated body is immersed in a dye 4 solution thereby adsorbing a dye 4 to the porous semiconductor layer 5 of the laminated body and then an electrolyte 6 is permeated into the porous semiconductor layer 5 and the porous spacer layer 7 of the laminated body from a front surface of the laminated body. Then an opposing electrode layer 8 is laminated on the porous spacer layer 7. The details are explained below using FIG. 9. The light-transmitting substrate 2 which has the laminated body thereon is immersed in a dye 4 solution thereby adsorbing a dye 4 to the porous semiconductor layer 5 (see FIG. 9(a) to (d)) in the same manner of Example 2, and then an electrolyte 6 is permeated from a front surface of the laminated body into the porous semiconductor layer 5 and the porous spacer layer 7 (see FIG. 9(e)).

Then, an opposing electrode layer 8, an extract electrode 9 and the other electrode are formed on the porous spacer layer 7 in the same manner of Example 2, and then a sealing layer is formed (see FIG. 9(f),(g)). In this case, no through hole is necessary to inject the electrolyte 6 into the device.

### Fourth Embodiment of Manufacturing Method

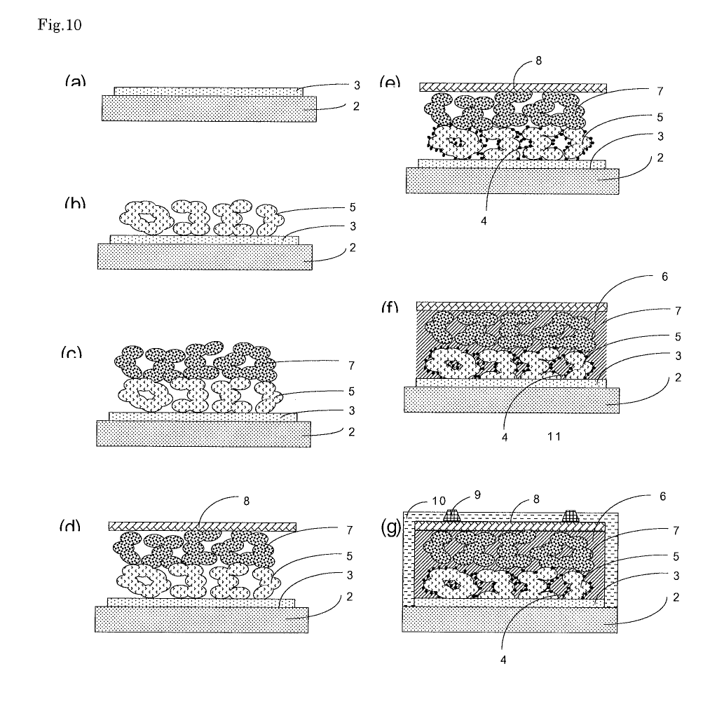

The fourth manufacturing method is for manufacturing a photoelectric conversion device shown in FIG. 1. That is, a light-transmitting conductive layer 3, a porous semiconductor layer 5, a porous spacer layer 7 and an opposing layer 8 are formed in this order on a light-transmitting substrate 2 to form a laminated body on a substrate. Then, the laminated body is immersed in a dye 4 solution thereby adsorbing a dye 4 to the porous semiconductor layer 5 from a side surface of the laminated body. Then an electrolyte 6 is permeated into the porous spacer layer 7 and the porous semiconductor layer 5 from a side surface of the laminated body. The details are explained below using FIG. 10. An opposing electrode layer 8 is laminated on the laminated body to form another laminated body (see FIG. 10(a) to (d)).

Then the laminated body is immersed in a dye solution thereby adsorbing a dye 4 to the porous semiconductor layer 5 from a side surface of the laminated body (see FIG. 10(e)). Then an electrolyte 6 is permeated into the porous spacer layer 7 and the porous semiconductor layer 5 from at least a side surface of the laminated body (see FIG. 10(f)). Finally, a collecting electrode 9 and a sealing layer 10 are formed (see FIG. 10(g)).

### <Another Embodiment>

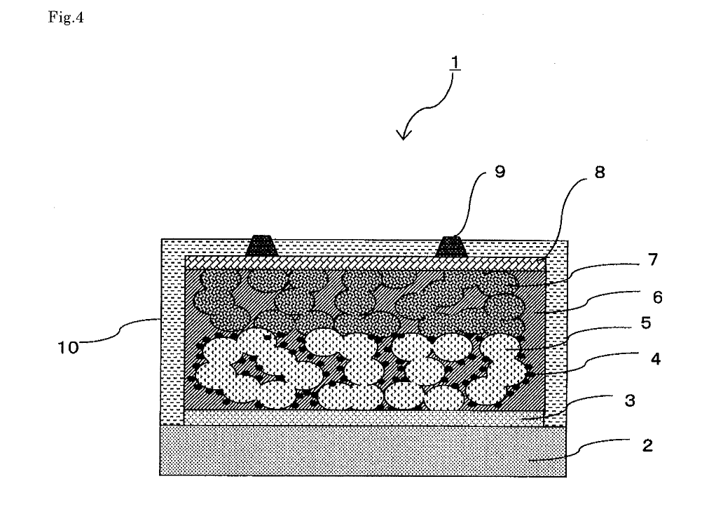

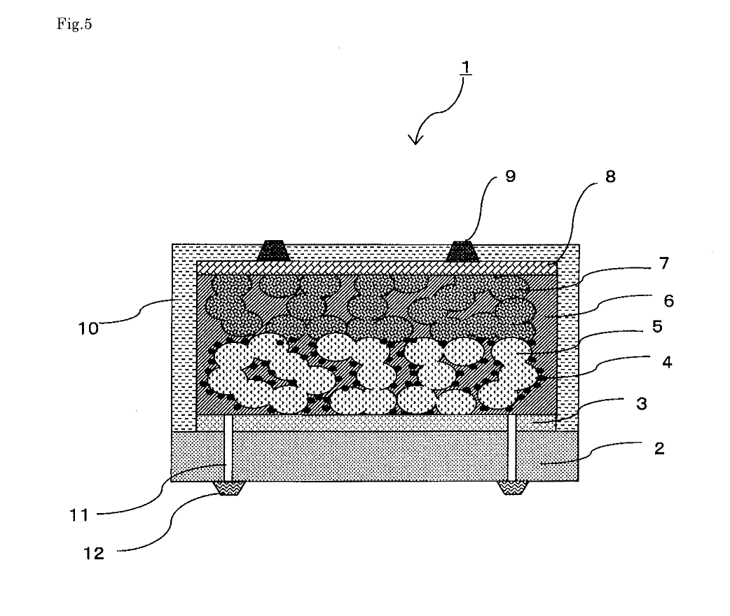

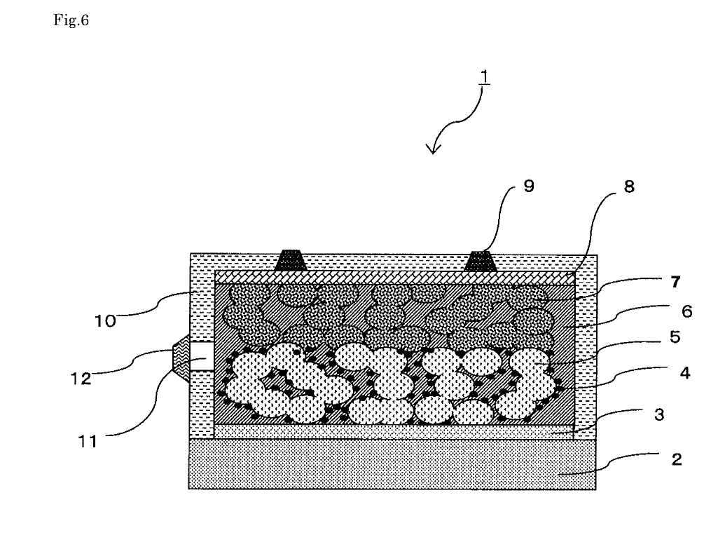

Other embodiments according to the present invention are explained in detail using FIG. 4 to 6 as follows. Photoelectric conversion device shown in FIGS. 5 and 6 are the same as that shown in FIG. 4 except through holes 11 and a sealing part 12 which closes the through holes. Therefore, the same parts are denoted by the same reference numeral and are not explained in detail.

The photoelectric conversion device 21 shown in FIG. 4 includes a laminated body. The laminated body includes an light-transmitting conductive layer 3, a porous semiconductor layer 5 that adsorbs (supports) a dye 4 and contains the electrolyte 6, a permeation layer into which an electrolyte 6 solution can permeate and a opposing electrode layer 8 laminated in this order on the light-transmitting substrate 2. A sealing layer 10 is formed on the upper surface and the side surface of the laminated body, and a collecting electrode 9 is formed if necessary.

The permeation layer 27 quickly absorbs and permeates the electrolyte 6 solution by a capillary phenomenon. Therefore, the electrolyte 6 solution can be quickly permeated into the entire permeation layer 27 and also the electrolyte 6 solution can be permeated through whole surface of the porous semiconductor layer 5 at a side of the permeation layer 27 to inside of the porous semiconductor layer 5.

According to the present invention, the electrolyte 6 may be a liquid, and may be a chemical gel that is a liquid phase until permeation into the permeation layer 27 is completed and is converted into a gel after permeation. Phase change from a liquid into a gel of a chemical gel can be performed by heating.

Next, the respective elements constituting the photoelectric conversion device 21 described above are described in detail below.

### <Light-Transmitting Substrate>

A substrate with high transmittance for at least visible light may be used as a light-transmitting substrate 2. For example, a white plate glass substrate with thickness of 0.7 mm having transmittance of 92% or more for the light with the wave length of 400 to 1100 nm can be used. Also polyethylene terephthalate (PET) or polycarbonate (PC) having 90% of transmittance for visible light can be used. A substrate preferably having transmittance of 90% or more for visible light can be used. The material of the light-transmitting substrate may be glass such as white plate glass, soda glass or borosilicate glass, an inorganic material such as ceramics, a resin material such as polyethylene terephthalate (PET), polycarbonate (PC), acryl, polyethylene naphthalate (PEN) or polyimide or an organic inorganic hybrid material.

The thickness of the light-transmitting substrate 2 may be in the range from 0.005 to 5 mm, and preferably from 0.01 to 2 mm in view of the mechanical strength.

### <Light-Transmitting Conductive Layer>

As the light-transmitting conductive layer 3, the same Light-transmitting conductive layer 3 as in the above-mentioned embodiment can be used.

### <Porous Semiconductor Layer>

As the porous semiconductor layer 5, the same porous semiconductor layer 5 as in the above-mentioned embodiment can be used. In addition, the porous semiconductor layer 5 is preferably a porous n-type oxide-semiconductor layer that includes titanium dioxide and contains a large number of fine pores (pore size is in the range from about 10 to 40 nm and a conversion efficiency shows a peak at 22 nm) therein. When the pore size of the porous semiconductor layer 5 is less than 10 nm, immersion and adsorption of the dye 4 are inhibited and a sufficient adsorption amount of the dye 4 is not obtained. Also, diffusion of the electrolyte 6 is inhibited and diffusion resistance increases, thus deteriorating the conversion efficiency. When the size exceeds 40 nm, the specific surface area of the porous semiconductor layer 5 decreases. However, when the thickness must be increased so as to ensure the adsorption amount of the dye 4, it becomes hard to transmit light when the thickness is too large. Therefore, the dye 4 cannot absorb light and also the migration length of charges injected into the porous semiconductor layer 5 increases to cause large loss due to rebonding of charges. Furthermore, diffusion length of the electrolyte 6 also increases and diffusion resistance increases, thus deteriorating the conversion efficiency.

### <Permeation Layer>

The permeation layer 27 is preferably a porous thin film obtained by sintering fine particles of aluminum oxide wherein the electrolyte 6 solution can be permeated into the permeation layer 27 by a capillary phenomenon and the solution is held by surface tension. As shown in FIG. 4, the permeation layer 27 is formed on the porous semiconductor layer 5. The state where the electrolyte 6 solution is held by surface tension in the permeation layer 27 is a state of preventing leakage of the electrolyte 6 solution adsorbed into the permeation layer 27 to the exterior, and the state can be easily discriminated by visual observation.

The arithmetic mean roughness of the surface or a fractured surface of the permeation layer 27 is preferably larger than the arithmetic mean roughness of the surface or a fractured surface of the porous semiconductor layer 5. Therefore, the mean grain size of fine grains constituting the permeation layer 27 is larger than that of the porous semiconductor layer 5. In this case, since the pore size in the permeation layer 27 increases, a large amount of the electrolyte 6 can exist in the permeation layer 27 adjacent to the opposing electrode layer 3, and thus electric resistance of the electrolyte 6 contained in the permeation layer 27 decreases and the conversion efficiency can be improved.

The permeation layer 27 can maintain a gap between the porous semiconductor layer 5 and the opposing electrode layer 8 to be narrow and constant. Therefore, it is preferred that the permeation layer 27 has a thickness that is uniform, is as thin as possible, and is porous so as to contain the dye 4 solution and the electrolyte 6 solution. As the thickness of the permeation layer 27 decreases, namely, the oxidation-reduction reaction distance or the hole transportation distance decreases, the conversion efficiency improves. Also, when the thickness of the permeation layer 27 becomes more uniform, a large-area photoelectric conversion device with high reliability can be realized.

The thickness of the permeation layer 27 is preferably in the range from 0.01 to 300 μm, and more preferably from 0.05 to 50 μm. When the thickness is less than 0.01 μm, the amount of the electrolyte 6 solution held by the permeation layer 27 decreases and thus electric resistance of the electrolyte 6 increases and the conversion efficiency is likely to deteriorate. In contrast, when the thickness exceeds 300 μm, a gap between the porous semiconductor layer 5 and the opposing electrode layer 8 increases and thus electric resistance due to the electrolyte 6 increases and the conversion efficiency is likely to deteriorate.

When the permeation layer 27 includes insulator grains, the material is preferably Al₂O₃, SiO₂, ZrO₂, CaO, SrTiO₃ or BaTiO₃. Of these materials, Al₂O₃ is excellent in insulating properties for preventing short circuiting between the opposing electrode layer 8 and the porous semiconductor layer 5, and mechanical strength (hardness). Also, Al₂O₃ has a white color and therefore it does not absorb light with a specific color and preferably prevents deterioration of the conversion efficiency.

Also, when the permeation layer 27 includes oxide-semiconductor grains, the material is preferably TiO₂, SnO₂, ZnO, CoO, NiO, FeO, Nb₂O₅, Bi₂O₃, MoO₂, Cr₂O₃, SrCu₂O₂, WO₃, La₂O₃, Ta₂O₅, CaO—Al₂O₃, In₂O₃, Cu₂O, CuAlO, CuAlO₂ or CuGaO₂, and MoS₂. Of these materials, TiO₂ adsorbs the dye 4 and can contribute to an improvement in the conversion efficiency. Also, TiO₂ is a semiconductor and thus it can suppress short circuiting between the opposing electrode layer 8 and the porous semiconductor layer 5 from occurring.

When the permeation layer 27 is a porous body including a collection of these granular bodies, acicular bodies, columnar bodies and/or the like, the electrolyte 6 solution can be contained, thus allowing improved conversion efficiency. The mean grain size or the mean fiber diameter of the granular body, the acicular body and the columnar body, each constituting the permeation layer 27, are preferably in the range from 5 to 800 nm, and more preferably from 10 to 400 nm. This is because miniaturization of the mean grain size or the mean fiber diameter of the material is not possible when the mean grain size is lower than the lower limit of 5 nm, and the sintering temperature increases when the mean grain size exceeds the upper limit of 800 nm.

When the permeation layer 27 is a porous body, the surface of the permeation layer 27 or the porous semiconductor layer 5 and the interface include an uneven face, bringing about a light confinement effect, thus making possible further improvement of the conversion efficiency.

The low-temperature growth method of the permeation layer 27 is preferably an electrodeposition method, a cataphoretic electrodeposition method or a hydrothermal synthesis method.

Regarding the permeation layer 27, the arithmetic mean roughness (Ra) of the surface or the surface of a fractured surface is preferably 0.1 μm or more, more preferably from 0.1 to 1.0 μm, and still more preferably from 0.1 to 0.5 μm, and further more preferably from 0.1 to 0.3 μm. When the arithmetic mean roughness (Ra) of the surface or the surface of a fractured surface of the permeation layer 27 is less than 0.1 μm, it becomes difficult to adsorb the dye 4 solution or the electrolyte 6 solution. In contrast, when the arithmetic mean roughness (Ra) of the surface or the surface of a fractured surface of the permeation layer 27 exceeds 1.0 μm, adhesion between the permeation layer 27 and the porous semiconductor layer 5 is likely to deteriorate. Furthermore, when Ra exceeds 1 μm, it becomes difficult to form the permeation layer 27. Here, Ra is defined in conformity to JIS-B-0601 and ISO-4287.

The arithmetic mean roughness (Ra) of the surface or the surface of a fractured surface of the permeation layer 27 approximately corresponds to the pore size in the interior of the permeation layer 27 and the pore size becomes approximately 0.1 μm when Ra is 0.1 μm.

Ra of the surface of the permeation layer 27 is measured by the following procedure. Using a probe type surface roughness tester, for example, SURFTEST (SJ-400) manufactured by Mitutoyo Corporation, the surface of the permeation layer 27 is measured. The method and the procedure of the measurement may be a method and a procedure for evaluation of a profile of the surface in conformity to JIS-B-0633 and ISO-4288. As the measuring position, a position with surface defects such as a scratch must be avoided. When the surface of the permeation layer 27 is isotropic, the measuring resistance, namely, the evaluation length, is appropriately set according to the value of Ra. For example, when Ra is more than 0.02 μm and is 0.1 μm or less, the evaluation length is set to 1.25 mm. In this case, the cut-off value for a roughness curve is set to 0.25 mm. The arithmetic mean roughness (Ra) of the surface or the surface of a fractured surface of the permeation layer 27 is measured in the same manner as in the case of the surface of the permeation layer 27.

The permeation layer 27 is fractured by the following procedure. First, the surface opposite the light-transmitting conductive layer 3 of the light-transmitting substrate 2 is scratched using a diamond cutter. The surface is scratched such that the scratch can be visually observed without causing generation of powders. Using pliers, a laminated body is fixed and the laminated body including the permeation layer 27 is fractured along the scratch formed on the light-transmitting substrate 2.

Also, the scratched light-transmitting substrate 2 may be fractured by the following procedure. First, a laminated body is placed on a block-shaped stand while facing the light-transmitting substrate 2 upwardly. In this case, the laminated body is fixed in a state where the edge of the block-shaped stand is made to be parallel to the scratch formed on the light-transmitting substrate 2 and also the scratch formed on the light-transmitting substrate 2 is kept in air while being about 1 mm apart from the edge of the block-shaped stand. Then, a tabular jig with a width longer than that of the laminated body, for example, a stainless steel plate, is disposed on both sides of the scratch formed on the light-transmitting substrate 2. The laminated body including the permeation layer 27 is fractured by downwardly pressing the jig kept on the portion kept in air of the laminated body while fixing the jig disposed on the portion of the laminated body on the block-shaped stand. Upon the fracturing of the permeation layer 27, the fractured surface preferably has a linear shape because it becomes easy to observe the fractured surface.

The permeation layer 27 is preferably a porous body with porosity in the range from 20 to 80%, and more preferably from 40 to 60%. When the porosity is less than 20%, it becomes difficult to adsorb the dye 4 solution or the electrolyte 6 solution. In contrast, when the porosity exceeds 80%, adhesion between the permeation layer 27 and the porous semiconductor layer 5 may deteriorate.

The porosity of the permeation layer 27 can be obtained by the following procedure. Using a gas adsorption measuring device, an isothermal adsorption curve of a sample is determined by a nitrogen gas adsorption method and the volume of pore is determined by the BJH method, the CI method or the DH method, and then the porosity can be obtained from the resulting volume of pores and density of grains of the sample.

When the porosity of the permeation layer 27 is increased in the above range, the dye 4 solution is adsorbed more quickly and the dye 4 can be securely adsorbed to the porous semiconductor layer 5. Furthermore, resistance of the electrolyte 6 decreases, thus making it possible to further improve the conversion efficiency. In order to form the permeation layer 27 with large porosity, for example, a paste prepared by mixing fine particles (mean particle size: 31 nm) of aluminum oxide (Al₂O₃) with polyethylene glycol (molecular weight: about 20,000) is fired. In this case, a mixture prepared by mixing 70% by weight of fine particles (mean particle size: 31 nm) of aluminum oxide with 30% by weight of fine particles (mean particle size: 180 nm) having a larger mean particle size of titanium oxide (TiO₂) may be used. Larger porosity can also be obtained by adjusting the weight ratio, the mean particle size and the material.

In order to hold the electrolyte 6 solution permeated into the permeation layer 27 by surface tension, the pore size of the permeation layer 27 is adjusted to a proper value according to the surface tension and density of the electrolyte 6 solution, or the contact angle between the electrolyte 6 solution and the permeation layer 27. For example, when the permeation layer 27 is formed by using an electrolyte 6 solution prepared by mixing ethylene carbonate, acetonitrile or methoxypropionitrile with tetrapropylammonium iodide, lithium iodide or iodine and using aluminum oxide or titanium oxide, the electrolyte 6 solution can be held in the permeation layer 27 when pore size of the permeation layer 27 is adjusted to 1 μm or less.

The permeation layer 27 made of aluminum oxide is formed by the following procedure. First, acetylacetone is added to an Al₂O₃ fine powder and the mixture is kneaded with deionized water. After stabilizing with a surfactant, polyethylene glycol is added to a paste of aluminum oxide. The paste thus prepared is applied on an porous semiconductor layer 5 at a constant speed by a doctor blade method or a bar coating method, and then subjected to a heat treatment in atmospheric air at 300 to 600° C., preferably at 400 to 500° C., for 10 to 60 minutes, preferably for 20 to 40 minutes to form a permeation layer 27.

### <Opposing Electrode Layer, Collecting Electrode Layer and Sealing Layer>

As the opposing electrode layer 8, the collecting electrode layer 9 and the sealing layer 10, the same opposing electrode layer 8, the collecting electrode layer 9 and sealing layer 10 as in the above-mentioned embodiment can be used, respectively. As the opposing electrode layer 8, a catalyst layer and a conductive layer (not shown) are preferably laminated in this order from a side of the permeation layer 25.

The sealing layer 10 shown in FIG. 4 to FIG. 6 includes layered bodies such as a transparent resin layer or a non-transparent resin layer, a glass layer formed by heating and solidifying a low melting point glass powder, and a sol-gel glass layer formed by curing a solution of a silicone alkoxide using a sol-gel method; tabular bodies such as a plastic plate and a glass plate; or foil-like bodies such as a thin metal film (sheet), or layered bodies, tabular bodies and foil-like bodies may be used in combination.

### <Dye>

As dye 4, the same dye 4 as in the above-mentioned embodiment can be used. The method of adsorbing the dye 4 into the porous semiconductor layer 5 can be the same method as used in the above-mentioned embodiment. For example, the porous semiconductor layer 5 formed on the light-transmitting substrate 2 is immersed in a solution containing the dye 4 dissolved therein.

As the solvent of the solution into which the dye 4 is dissolved, for example, alcohols such as ethanol; ketones such as acetone; ethers such as diethylether; and nitrogen compounds such as acetonitrile are used alone or a mixture of two or more kinds of them. The concentration of the dye 4 in the solution is preferably in the range from about 5×10⁻⁵ to 2×10⁻³ mol/l (liter: 1,000 cm³).

There are no restrictions on the solution and temperature conditions of the atmosphere in the case of immersing the light-transmitting substrate 2 with the porous semiconductor layer 5 formed thereon in the solution containing the dye 4 dissolved therein. For example, the light-transmitting substrate 2 is immersed in the solution under atmospheric pressure or a vacuum at room temperature or while heating. The immersion time can be appropriately controlled according to the kind of dye 4 and solution, and the concentration of the solution. Consequently, the dye 4 can be adsorbed to the porous semiconductor layer 5.

### <Electrolyte>

As the electrolyte 6, the same electrolyte 6 as in the above-mentioned embodiment can be used.

### (Manufacturing Method)

According to the present invention, photoelectric conversion devices 21 in the other embodiments is manufactured by substituting the porous spacer layer 7 to the permeating layer 27 in the same method as that of the first to fourth manufacturing methods.

For example, the method of manufacturing the photoelectric conversion device 21 showed in FIG. 4 is as follows. A light-transmitting conductive layer 3, a porous semiconductor layer 5, a permeating layer 27 and an opposing electrode layer 8 are laminated in this order on the light-transmitting substrate 2. Then, the laminated body is immersed in a dye 4 solution thereby adsorbing the dye 4 to the porous semiconductor layer 5 through the permeation layer 27. Then, the electrolyte 6 solution is permeated into the porous semiconductor layer 5 through the permeation layer 27.

In this case, when the dye 4 is adsorbed to the porous semiconductor layer 5, the laminated body is immersed in the dye 4 solution and the dye 4 is absorbed from the side surface of the laminated body and through the permeating layer 27 resulting in easy and quick permeation of the electrolyte.

In this case, a plurality of through holes 11 (shown in FIG. 5) may be formed such that the through holes pass completely through the light-transmitting substrate 2 and the light-transmitting conductive layer 3. The electrolyte 6 solution is injected from the through holes 11 thereby permeating electrolyte 6 solution into the porous semiconductor 5 from the side surface of the laminated body and permeating layer 27. Finally, the through holes 11 can be sealed.

Alternatively, a plurality of through holes 11 (shown in FIG. 6) may be formed at the side surface of the laminated body such that the through holes 11 pass the sealing layer 10. Then the electrolyte 6 solution is injected through the through holes 11 thereby permeating electrolyte 6 solution into the porous semiconductor 5 from the side surface of the laminated body and permeating layer 27. Finally, the through holes 11 can be sealed.

Applications of the photoelectric conversion device 1, 21 according to the present invention are not limited to solar batteries. The photoelectric conversion device can be applied to applications having a photoelectric conversion function and can be applied to various photodetectors and optical sensors.

### <Photoelectric Power Generation Device>

A photoelectric power generation device can be provided such that the above photoelectric conversion device 1, 21 is utilized as means of electrical power generation, and the electrical power generated by the means of electrical power generation is supplied to a load. Namely, one photoelectric conversion device 1, 21 described above is used or, when using a plurality of photoelectric conversion devices, those connected in series, in parallel or in serial-parallel are used as means of electrical power generation and electrical power may be directly supplied to a DC load from the means of electrical power generation. Also, there can be used an electrical power generation device capable of supplying the electrical power to a commercial power supply system or an AC load of various electrical equipment after converting means of photoelectrical power generation into a suitable AC electric power through electrical power conversion means such as an inverter. Furthermore, such an electrical power generation device can be utilized as a photoelectric power generation device of solar power generating systems of various aspects by building with a sunny aspect. Consequently, a photoelectric power generation device with high efficiency and durability can be provided.

The photoelectric conversion device of the present invention is described below by way of Examples and Comparative Examples, but the present invention is not limited only to the following Examples.

### Example 1

A photoelectric conversion device 1 shown in FIG. 2 was manufactured by the following procedure.

First, as a light-transmitting substrate 2, a commercially available glass substrate (measuring 1 cm in length×2 cm in width) with a light-transmitting conductive layer made of a fluorine-doped tin oxide, was used.

A porous semiconductor layer 5 made of titanium dioxide was formed on the light-transmitting substrate 2. The porous semiconductor layer 5 was formed by the following procedure. First, acetylacetone was added to a TiO₂ anatase powder (mean particle size: 20 nm) and then the mixture was kneaded with deionized water to prepare a titanium oxide paste stabilized with a surfactant. The paste thus prepared was applied on a light-transmitting conductive layer 3 formed on the light-transmitting substrate 2 at a constant speed using a doctor blade method and then fired in atmospheric air at 450° C. for 30 minutes.

Then, a porous spacer layer 7 made of aluminum was formed on the light-transmitting substrate 2. The porous spacer layer 7 was formed by the following procedure. First, acetylacetone was added to an Al₂O₃ powder (mean particle size: 31 nm) and the mixture was kneaded with deionized water to prepare an alumina paste stabilized with a surfactant. The paste thus prepared was applied on the light-transmitting substrate 2 at a constant speed using a doctor blade method and then fired in atmospheric air at 450° C. for 30 minutes.

A platinum layer was deposited on the porous spacer layer 7 by a sputtering method using a Pt target to form an opposing electrode layer with a thickness about 50 nm. A Ti film was deposited on the platinum layer by sputtering method using a Ti target so as to control sheet resistance to 2Ω/□ (square) to form a laminated body.

Then, an Ag paste was applied to a portion of the Ti film and heated to form an extract electrode. On the other hand, a solder terminal was formed using ultrasonic waves to form an extract electrode on a light-transmitting conductive layer 3.

Then, a sheet made of an olefinic resin serving as a sealing member was covered on the opposing electrode layer 8 followed by heating to form a sealing layer 10.

While rotating an electrodeposited diamond bar around an axis at high speed, the back surface of the light-transmitting substrate 2 was ground to form a plurality of through holes 11.

Then, the inside of the laminated body formed on the light-transmitting substrate 2 was evacuated through the through holes 11 and then a dye 4 solution was injected into the laminated body through the through holes 11. As the dye solution (the content of dye is 0.3 mmol/l), a solution prepared by dissolving the dye 4 (“N719”, manufactured by Solaronix SA Co.) in acetonitrile and t-butanol (1:1 in terms of volume ratio) as a solvent was used.

The inside of the laminated body was evacuated through the through holes 11 and then an electrolytic solution was injected into the laminated body through the through holes 11. In Example 1, as an electrolyte 6, iodine (I₂) and lithium iodide (LiI) in an acetonitrile solution were used as the liquid electrolyte.

Regarding the photoelectric conversion device 1 according to the present invention, photoelectric conversion characteristics were evaluated. The evaluation was performed by irradiation with light having a predetermined intensity and a predetermined wavelength and measuring photoelectric conversion efficiency (unit: %) that indicates electrical characteristics of the photoelectric conversion device. The electrical characteristics were measured by a method in conformity to JIS C 8913 using a solar simulator (WXS155S-10, manufactured by WACOM Co.).

As a result of the evaluation, it was found that photoelectric conversion efficiency is 3.2% at AM 1.5 and 100 mW/cm².

As described above, it could be confirmed that the photoelectric conversion device 1 of the present invention can be simply manufactured and also good conversion efficiency is obtained in Example 1.

### Example 2

A photoelectric conversion device 1 shown in FIG. 3 was manufactured by the following procedure.

First, as a light-transmitting substrate 2, a commercially available glass substrate (measuring 1 cm in length×2 cm in width) with a light-transmitting conductive layer made of a fluorine-doped tin oxide, was used.

A porous semiconductor layer 5 made of titanium dioxide was formed on the light-transmitting substrate 2 in the same manner as in Example 1.

Then, a porous spacer layer 7 made of aluminum was formed on the light-transmitting substrate 2 in the same manner as in Example 1.

As the solvent in which the dye 4 (“N719”, manufactured by Solaronix SA Co.) is dissolved, acetonitrile and t-butanol (1:1 in volume ratio) were used. The light-transmitting substrate 2 with the laminated body formed thereon was immersed in a solution containing the dye 4 dissolved therein (the content of dye is 0.3 mmol/l) for 12 hours thereby adsorbing the dye 4 to the porous semiconductor layer 5. Then, the light-transmitting substrate 2 was washed with ethanol and dried.

A platinum layer was deposited on the porous spacer layer by a sputtering method using a Pt target to form an opposing electrode layer with a thickness about 50 nm. A Ti layer was deposited on the platinum layer by sputtering method using a Ti target so as to control sheet resistance to 2Ω/□ (square) to form a laminated body.

Then, an Ag paste was applied to a portion of the Ti layer and heated to form an extract electrode. On the other hand, a solder was soldered using ultrasonic waves to form an extract electrode on a light-transmitting conductive layer 3 made of a fluorine-doped tin dioxide.

Then, a sheet made of an olefinic resin serving as a sealing member was covered on thus prepared light-transmitting substrate 2, followed by heating to form a sealing layer 10.

On a side of the sealing layer 10, the through holes (reference numeral 11 in FIG. 3) were formed by cutting a side portion of the sealing layer 10 and an electrolyte 6 was injected from a side surface of the laminated body into the laminated body through the through holes 11. In Example 2, iodine (I₂) and lithium iodide (LiI) in an acetonitrile solution was used as the liquid electrolyte 6. The liquid electrolyte as an electrolytic solution was permeated into the laminated body from a side surface and then the through holes 11 were closed by the same sealing material (reference numeral 12 in FIG. 3) as that in the sealing layer 10.

Regarding the photoelectric conversion device 1 thus manufactured, photoelectric conversion characteristics were evaluated in the same manner as in Example 1. As a result, it was found that photoelectric conversion efficiency is 4.1% at AM 1.5 and 100 mW/cm².

As described above, it could be confirmed that the photoelectric conversion device 1 of the present invention can be simply manufactured and also good conversion efficiency is obtained in Example 2.

### Example 3

A photoelectric conversion device 1 shown in FIG. 3 was manufactured by the following procedure.

First, as a light-transmitting substrate 2, a commercially available glass substrate (measuring 1 cm in length×2 cm in width) with a light-transmitting conductive layer made of a fluorine-doped tin oxide, was used.

A porous semiconductor layer 5 made of titanium dioxide was formed on the light-transmitting substrate 2 in the same manner as in Example 1.

Then, a porous spacer layer 7 made of aluminum was formed on the light-transmitting substrate 2 in the same manner as in Example 1.

A platinum layer was deposited on the porous spacer layer by a sputtering method using a Pt target to form an opposing electrode layer with a thickness about 50 nm. A Ti layer was deposited on the platinum layer by sputtering method using a Ti target so as to control sheet resistance to 2Ω/□ (square) to form a laminated body.

Then, an Ag paste was applied to a portion of the Ti layer and heated to form an extract electrode. On the other hand, a solder terminal was formed using ultrasonic waves to form an extract electrode on a light-transmitting conductive layer 3 made of a fluorine-doped tin dioxide.

Then, a sheet made of an olefinic resin serving as a sealing member was covered on the opposing electrode layer 8 followed by heating to form a sealing layer 10.

On a side of the sealing layer 10, the same dye 4 as that in the Example 1 was formed by cutting a side portion of the sealing layer 10 and the dye solution was injected into the laminated body through the through holes 11.

The same electrolyte as that in the Example 1 was permeated into the laminated body from a side surface thereof and then the through holes 11 were closed by the same sealing material (reference numeral 12 in FIG. 3) as that in the sealing layer 10.

Regarding the photoelectric conversion device 1 thus manufactured, photoelectric conversion characteristics were evaluated in the same manner as in Example 1. As a result, it was found that photoelectric conversion efficiency is 3.6% at AM 1.5 and 100 mW/cm².

As described above, it could be confirmed that the photoelectric conversion device 1 of the present invention can be simply manufactured and also good conversion efficiency is obtained in Example 3.

### Example 4

A photoelectric conversion device 21 shown in FIG. 4 was manufactured by the following procedure.

First, as a light-transmitting substrate 2, a commercially available glass substrate (measuring 1 cm in length×2 cm in width) with a light-transmitting conductive layer made of a fluorine-doped tin oxide, was used.

Then, on the light-transmitting substrate 2, a porous semiconductor layer 5 made of titanium dioxide was formed. The porous semiconductor layer 5 was formed by the following procedure. First, acetylacetone was added to a TiO₂ anatase powder (mean particle size: 20 nm) and the mixture was kneaded with deionized water to prepare a titanium oxide paste stabilized with a surfactant. The paste thus prepared was applied on the light-transmitting substrate 2 at a constant speed using a doctor blade method and then fired in atmospheric air at 450° C. for 30 minutes. The arithmetic mean roughness of the surface of the porous semiconductor layer 5 was 0.054 μm. The arithmetic mean roughness of the surface of the porous semiconductor layer 5 was measured using a probe type surface roughness tester (“SURFTEST SJ-401”, manufactured by Mitutoyo Corporation). The arithmetic mean roughness of the surface was measured under the conditions of a measuring length of 1.25 mm and a cut-off value of 0.25 mm by a method in conformity to ISO-4288 using a Gauss-shaped filter.

A permeation layer 27 made of aluminum oxide was formed on the semiconductor layer 5. The permeation layer 27 was formed by the following procedure. First, acetylacetone was added to Al₂O₃ powders (mean particle size: 31 nm) and kneaded with deionized water to prepare an aluminum oxide paste stabilized with a surfactant. The paste thus prepared was applied on the porous semiconductor layer 5 at a constant speed using a doctor blade method, and then subjected to a heat treatment in atmospheric air at 450° C. for 30 minutes. The arithmetic mean roughness of the surface of the permeation layer 27 was 0.276 μm. The arithmetic mean roughness of the surface of the permeation layer 27 was measured using a probe type surface roughness tester (“SURFTEST SJ-401”, manufactured by Mitutoyo Corporation). The arithmetic mean roughness of the surface was measured under the conditions of a measuring length of 4 mm and a cut-off value of 0.8 mm by a method in conformity to ISO-4288 using a Gauss-shaped filter.

A platinum layer was deposited on the permeation layer 27 by a sputtering method using a Pt target to form an opposing electrode layer 8 with a thickness about 50 nm so as to control sheet resistance to 0.6Ω/□ (square) to form a laminated body.

A portion of the laminated body was mechanically removed to expose a side surface of a permeation layer 27, and then the laminated body was immersed in the same dye solution for 38 hours thereby adsorbing the dye 4 to the porous semiconductor layer 5 through the permeation layer 27. As the dye solution (the content of the dye is 0.3 mmol/l), a solution prepared by dissolving the dye 4 (“N719”, manufactured by Solaronix SA Co.) in acetonitrile and t-butanol (1:1 in terms of volume ratio) as a solvent was used.

Then, a solder terminal was formed using ultrasonic waves to form an extract electrode on the light-transmitting conductive layer 3 including a fluorine-doped tin dioxide. Furthermore, an Ag paste was applied to a portion of the platinum layer and heated to form an extract electrode.

Then, an electrolytic solution was permeated into the porous semiconductor layer 5 through the permeation layer 27. Then, a sheet made of an olefinic resin serving as a sealing member was covered on the opposing electrode layer 8 followed by heating to form a sealing layer 10.

Regarding the photoelectric conversion device 21 thus manufactured, photoelectric conversion characteristics were evaluated in the same manner as in Example 1. As a result, it was found that photoelectric conversion efficiency is 5.5% at AM 1.5 and 100 mW/cm².

As described above, it could be confirmed that the photoelectric conversion device 21 of the present invention can be simply manufactured and also good conversion efficiency is obtained in Example 4.

### Example 5

A photoelectric conversion device 21 shown in FIG. 5 was manufactured by the following procedure.

As a light-transmitting substrate 2, a commercially available glass substrate (measuring 3 cm in length×2 cm in width) with a light-transmitting conductive layer made of a fluorine-doped tin oxide, was used. While rotating an electrodeposited diamond bar around an axis at high speed, the back surface of the light-transmitting substrate 2 was drilled to form a plurality of through holes 11.

On the light-transmitting substrate 2, a porous semiconductor layer 5 made of titanium dioxide was formed in the same manner as in Example 4. The arithmetic mean roughness of the surface of the porous semiconductor layer 5 was 0.059 μm. The arithmetic mean roughness of the surface of the porous semiconductor layer 5 was measured using a probe type surface roughness tester (“SURFTEST SJ-401”, manufactured by Mitutoyo Corporation). The arithmetic mean roughness of the surface was measured under the conditions of a measuring length of 1.25 mm and a cut-off value of 0.25 mm by a method in conformity to ISO-4288 using a Gauss-shaped filter.

On the semiconductor layer 5, a permeation layer 27 made of titanium oxide was formed. The permeation layer 27 was formed by the following procedure. First, acetylacetone was added to a mixed powder obtained by mixing two kinds of TiO₂ powders, a TiO₂ powder having a mean particle size of 20 nm and a TiO₂ powder having a mean particle size of 180 nm, in a mixing weight ratio of 10:2 and the mixture was kneaded with deionized water to prepare a titanium dioxide paste stabilized with a surfactant. The paste thus prepared was applied on the porous semiconductor layer 5 at a constant speed using a doctor blade method, and then subjected to a heat treatment in atmospheric air at 450° C. for 30 minutes. The arithmetic mean roughness of the surface of the permeation layer 27 was 0.129 μm. The arithmetic mean roughness of the surface of the permeation layer 27 was measured using a probe type surface roughness tester (“SURFTEST SJ-401”, manufactured by Mitutoyo Corporation). The arithmetic mean roughness of the surface was measured under the conditions of a measuring length of 4 mm and a cut-off value of 0.8 mm by a method in conformity to ISO-4288 using a Gauss-shaped filter.

A platinum layer was deposited on the permeation layer 27 by a sputtering method using a Pt target to form an opposing electrode layer 8 with a thickness about 200 nm so as to control sheet resistance to 0.6Ω/□ (square) to form a laminated body.

A portion of the laminated body was mechanically removed to expose a side surface of a permeation layer 27, and then the laminated body was immersed in the same dye solution as that in Example 4 for 38 hours thereby adsorbing the dye 4 to the porous semiconductor layer 5 through the permeation layer 27.

Then, a solder terminal was formed using ultrasonic waves to form an extract electrode on a light-transmitting conductive layer 3 including a fluorine-doped tin dioxide. Furthermore, an Ag paste was applied to a portion of the platinum layer and heated to form an extract electrode.

Then, a sheet made of an olefinic resin serving as a sealing member was covered on the opposing electrode layer 8 followed by heating to form a sealing layer 10.

Then, the inside of the laminated body formed on the conducting substrate 2 was evacuated through the through holes 11 and then the same electrolytic solution as in Example 4 was injected into the laminated body through the through holes 11. Furthermore, the through holes 11 were closed by the same sealing material (denoted by the reference numeral 12 in FIG. 5) as that in the sealing layer 10.

Regarding the photoelectric conversion device 21 thus manufactured, photoelectric conversion characteristics were evaluated in the same manner as in Example 1. As a result, it was found that photoelectric conversion efficiency is 4.6% at AM 1.5 and 100 mW/cm².

As described above, it could be confirmed that the photoelectric conversion device 21 of the present invention can be simply manufactured and also good conversion efficiency is obtained in Example 5.

### Example 6

A photoelectric conversion device 21 shown in FIG. 6 was manufactured by the following procedure.

As a light-transmitting substrate 2, a commercially available glass substrate (measuring 3 cm in length×2 cm in width) with a light-transmitting conductive layer made of a fluorine-doped tin oxide, was used.

On the light-transmitting substrate 2, a porous semiconductor layer 5 made of titanium dioxide was formed in the same manner as in Example 4. The arithmetic mean roughness of the surface of the porous semiconductor layer 5 was 0.060 μm. The arithmetic mean roughness of the surface of the porous semiconductor layer 5 was measured using a probe type surface roughness tester (“SURFTEST SJ-401”, manufactured by Mitutoyo Corporation). The arithmetic mean roughness of the surface was measured under the conditions of a measuring length of 1.25 mm and a cut-off value of 0.25 mm by a method in conformity to ISO-4288 using a Gauss-shaped filter.

On the semiconductor layer 5, a permeation layer 27 made of aluminum oxide was formed in the same manner as in Example 4. The arithmetic mean roughness of the surface of the permeation layer 27 was 0.226 μm. The arithmetic mean roughness of the surface of the permeation layer 27 was measured using a probe type surface roughness tester (“SURFTEST SJ-401”, manufactured by Mitutoyo Corporation). The arithmetic mean roughness of the surface was measured under the conditions of a measuring length of 4 mm and a cut-off value of 0.8 mm by a method in conformity to ISO-4288 F using a Gauss-shaped filter.

A platinum layer was deposited on the permeation layer 27 by a sputtering method using a Pt target to form an opposing electrode layer 8 with a thickness about 200 nm so as to control sheet resistance to 0.6Ω/□ (square) to form a laminated body.

A portion of the laminated body was mechanically removed to expose a side surface of a permeation layer 27, and then the laminated body was immersed in the same dye solution as that in Example 4 for 38 hours thereby adsorbing the dye 4 to the porous semiconductor layer 5 through the permeation layer 27.

Then, a solder was soldered using ultrasonic waves to form an extract electrode on a light-transmitting conductive layer 3 made of a fluorine-doped tin dioxide. Furthermore, an Ag paste was applied to a portion of the platinum layer and heated to form an extract electrode.

Then, a sheet of a sealing material made of an olefinic resin covered the conducting substrate 2, followed by heating to form a sealing layer 10. Furthermore, through holes 11 were formed by cutting out a portion of the sealing layer 10 and the same electrolyte 4 was injected from a side surface of the laminated body into the laminated body through the through holes 11 after the inside of the laminated bode was evacuated through the through holes. The liquid electrolyte was permeated into the porous semiconductor layer 5 through the permeation layer 27 and then the through holes 11 were closed by the same sealing member (denoted by the reference numeral 12 in FIG. 6) as that in the sealing layer 10.

Regarding the photoelectric conversion device 21 thus manufactured in the same manner of Example 1, photoelectric conversion characteristics were evaluated in the same manner as in Example 1. As a result, it was found that photoelectric conversion efficiency is 6.0% at AM 1.5 and 100 mW/cm².

As described above, it could be confirmed that the photoelectric conversion device 21 of the present invention can be simply manufactured and also good conversion efficiency is obtained in Example 6.

### Example 7

As a light-transmitting substrate 2, a commercially available glass substrate (measuring 3 cm in length×2 cm in width) with a light-transmitting conductive layer made of a fluorine-doped tin oxide, was used.

On the light-transmitting substrate 2, a porous semiconductor layer 5 made of titanium dioxide was formed in the same manner as in Example 4. The arithmetic mean roughness of the surface of the porous semiconductor layer 5 was 0.060 μm. The arithmetic mean roughness of the surface of the porous semiconductor layer 5 was measured using a probe type surface roughness tester (“SURFTEST SJ-401”, manufactured by Mitutoyo Corporation). The arithmetic mean roughness of the surface was measured under the conditions of a measuring length of 1.25 mm and a cut-off value of 0.25 mm by a method in conformity to ISO-4288 using a Gauss-shaped filter.

On the semiconductor layer 5, a permeation layer 27 made of titanium oxide was formed. The permeation layer 27 was formed by the following procedure. First, acetylacetone was added to TiO₂ powders (mean particle size: 20 nm) and kneaded with deionized water to prepare an titanium oxide paste stabilized with a surfactant. The paste thus prepared was applied on the porous semiconductor layer 5 at a constant speed using a doctor blade method, and then subjected to a heat treatment in atmospheric air at 450° C. for 30 minutes. The arithmetic mean roughness of the surface of the permeation layer 27 was 0.059 μm. The arithmetic mean roughness of the surface of the permeation layer 27 was measured using a probe type surface roughness tester (“SURFTEST SJ-401”, manufactured by Mitutoyo Corporation). The arithmetic mean roughness of the surface was measured under the conditions of a measuring length of 1.25 mm and a cut-off value of 0.25 mm by a method in conformity to ISO-4288 using a Gauss-shaped filter.

A platinum layer was deposited on the permeation layer 27 by a sputtering method using a Pt target to form an opposing electrode layer 8 with a thickness about 200 nm so as to control sheet resistance to 0.6Ω/□ (square) to form a laminated body.

A portion of the laminated body was mechanically removed to expose a side surface of a permeation layer 27, and then the laminated body was immersed in the same dye solution as that in Example 4 for 38 hours. Then the time was extended to 68 hours.

### Example 8

As a light-transmitting substrate 2, a commercially available glass substrate (measuring 3 cm in length×2 cm in width) with a light-transmitting conductive layer made of a fluorine-doped tin oxide, was used.

On the light-transmitting substrate 2, a porous semiconductor layer 5 made of titanium dioxide was formed in the same manner as in Example 4. The arithmetic mean roughness of the surface of the porous semiconductor layer 5 was 0.054 μm. The arithmetic mean roughness of the surface of the porous semiconductor layer 5 was measured using a probe type surface roughness tester (“SURFTEST SJ-401”, manufactured by Mitutoyo Corporation). The arithmetic mean roughness of the surface was measured under the conditions of a measuring length of 1.25 mm and a cut-off value of 0.25 mm by a method in conformity to ISO-4288 using a Gauss-shaped filter.

On the opposing electrode layer 5, a permeation layer 27 made of titanium dioxide was formed. The permeation layer 27 was formed by the following procedure. First, ethyl cellulose was added to TiO₂ obtained by hydrothermal synthesis and the mixture was kneaded with a terpineol solvent to prepare a titanium dioxide paste stabilized with a surfactant. The paste thus prepared was applied on a porous semiconductor layer 5 at a given rate using a screen printing method, and then fired in atmospheric air at 450° C. for 30 minutes. The arithmetic mean roughness of the surface of the permeation layer 27 was 0.538 μm. The arithmetic mean roughness of the surface of the permeation layer 27 was measured using a probe type surface roughness tester (“SURFTEST SJ-401”, manufactured by Mitutoyo Corporation). The arithmetic mean roughness of the surface was measured under the conditions of a measuring length of 4 mm and a cut-off value of 0.8 mm by a method in conformity to ISO-4288 using a Gauss-shaped filter.

A platinum layer was deposited on the permeation layer 27 by a sputtering method using a Pt target to form an opposing electrode layer 8 with a thickness about 200 nm so as to control sheet resistance to 0.6•/□ (square) to form a laminated body.

A portion of the laminated body was mechanically removed to expose a side surface of a permeation layer 27, and then the laminated body was immersed in the same dye solution as that in Example 4.

1. A photoelectric conversion device, comprising:
a single, substrate made of a light-transmitting material;
a conductive layer made of a light-transmitting material upon the transmitting substrate;
a porous semiconductor layer upon the conductive layer, said porous semiconductor layer containing a dye and containing an electrolyte;
a porous spacer layer upon the porous semiconductor layer, said porous spacer layer containing an electrolyte; and
an opposing electrode layer upon the porous spacer layer.

2. The photoelectric conversion device according to claim 1, further comprising a sealing layer covering a laminated body that comprises the conductive layer, the porous semiconductor layer, the porous spacer layer and the opposing electrode layer and fixed to the substrate and sealing the electrolyte within the laminated body.

3. The photoelectric conversion device according to claim 1, wherein the porous semiconductor layer comprises a sintered body containing oxide-semiconductor fine grains and the mean grain size of the oxide-semiconductor fine grains in the porous semiconductor layer is larger at the side of the spacer layer than at the side of the substrate.

4. The photoelectric conversion device according to claim 1, wherein the porous spacer layer contains fine grains of an insulator or a p-type semiconductor.

5. The photoelectric conversion device according to claim 1, further comprising an uneven interface between the porous spacer layer and the semiconductor layer.

6. The photoelectric conversion device according to claim 1, wherein the opposing electrode layer comprises a porous body containing the electrolyte.

7. The photoelectric conversion device according to claim 1, wherein the porous spacer layer is permeable to an electrolyte solution.

8. The photoelectric conversion device according to claim 7, wherein the arithmetic mean roughness of the surface or a fractured surface of the porous spacer layer is larger than the arithmetic mean roughness of the surface or a fractured surface of the porous semiconductor layer.

9. The photoelectric conversion device according to claim 7, wherein the arithmetic mean roughness of the surface or a fractured surface of the porous spacer layer is not less than 0.1 μm.

10. The photoelectric conversion device according to claim 7, wherein the porous spacer layer comprises a sintered body comprises grains of an insulator or an oxide.

11. The photoelectric conversion device according to claim 10, wherein the grains comprise an aluminum oxide or a titanium oxide.

12. The photoelectric conversion device according to claim 7, further comprising a sealing member covering the laminated body and fixed to the substrate, sealing the electrolyte within the laminated body.

13. (canceled)

14. (canceled)

15. (canceled)

16. (canceled)

17. (canceled)

18. (canceled)

19. (canceled)

20. A photoelectric conversion device, comprising:
a single substrate made of a light-transmitting material;
a conductive layer made of a light-transmitting material upon the substrate;
a porous semiconductor layer upon the conductive layer,
a porous spacer layer upon the porous semiconductor layer; and
an opposing electrode layer upon the porous spacer layer.

21. A method of manufacturing a photoelectric conversion device, comprising the steps of:
laminating a conductive layer, a porous semiconductor layer and a porous spacer layer in this order on a substrate;
laminating an opposing electrode layer on the porous spacer layer to form a laminated body that comprises the conductive layer, the porous semiconductor layer, the porous spacer layer and the opposing electrode layer;
adsorbing a dye on the porous semiconductor layer; and
permeating an electrolyte into the porous semiconductor layer and the porous spacer layer.

22. The method of manufacturing a photoelectric conversion device according to claim 21, further comprising a steps of:
forming a sealing layer sealing the laminated body on the substrate;
forming one or more through holes to penetrate the substrate and the opposing electrode layer;
injecting the dye and the electrolyte into the sealed laminated body through the through hole(s) followed by the steps of adsorbing the dye and permeating the electrolyte; and
sealing the through holes after the steps of adsorbing the dye and permeating the electrolyte.

23. The method of manufacturing a photoelectric conversion device according to claim 21, wherein the dye is adsorbed on the porous semiconductor layer by immersing the laminated body in a dye solution and then the opposing electrode layer is laminated followed by permeating the electrolyte from the side surface thereof into the porous semiconductor layer and the porous spacer layer.

24. The method of manufacturing a photoelectric conversion device according to claim 21, wherein the dye is adsorbed on the porous semiconductor layer by immersing the laminated body in a dye solution and then the electrolyte is permeated from the front surface thereof into the porous semiconductor layer and the porous spacer layer followed by laminating the opposing electrode layer.

25. The method of manufacturing a photoelectric conversion device according to claim 21, wherein the opposing electrode layer is laminated and then the dye is adsorbed from the side surface thereof on the porous semiconductor layer by immersing the laminated body in a dye solution followed by permeating the electrolyte from the side surface thereof into the porous semiconductor layer and the porous spacer layer.

26. The method of manufacturing a photoelectric conversion device according to claim 21, wherein the porous spacer layer is a porous spacer layer permeating an electrolyte solution thereinto and containing the permeated solution therein.

27. A photoelectric power generation device, comprising a plurality of the photoelectric conversion devices according to claim 1, connected in parallel or in series.
